(19) United States
(12) Patent Application Publication
(10) Pub. No.: US 2025/0285988 A1
(43) Pub. Date: Sep. 11, 2025

(54) DOPED WELL AND ALIGNMENT MARK FOR SEMICONDUCTOR DEVICES

(71) Applicant: Taiwan Semiconductor Manufacturing Co., Ltd., Hsinchu (TW)

(72) Inventors: Bau-Ming Wang, Kaohsiung City (TW); Liang-Yin Chen, Hsinchu (TW); Chien-Hao Chen, Chuangwei Township (TW)

(21) Appl. No.: 18/599,695

(22) Filed: Mar. 8, 2024

(51) Int. Cl. H01L 23/544; H01L 21/266; H01L 29/06; H01L 29/423; H01L 29/775; H01L 29/786

(52) U.S. Cl. CPC H01L 23/544; H01L 21/266; H10D 30/43; H10D 30/6735; H10D 30/6757; H10D 62/121; H01L 2223/54426

(57) ABSTRACT

In an embodiment, a semiconductor device includes a semiconductor substrate including a first fin and a second fin; a first well, a second well and an alignment mark in the semiconductor substrate; and an isolation layer over the first fin, the second fin, the semiconductor substrate, and the alignment mark. The first fin is in the first well, and the first well is doped with a first dopant having a first conductivity type. The second fin is in the second well, and the second well is doped with a second dopant having a second conductivity type different from the first conductivity type. The alignment mark includes a lower portion formed of a first material and an upper portion formed of a second material different from the first material.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3A, 3B and 4 to 9 illustrate intermediate stages in manufacturing wells and alignment marks of nano-FETs, in accordance with some embodiments.

FIGS. 10, 11A, 11B, 12A, 12B, 13, 14A, 14B, 15A, 15B, 16A, 16B, 17A, 17B, 18A, 18B, 19A, 19B, 19C, 20A, 20B, 20C, 20D, 21A, 21B, 21C, 22A, 22B, 23A, 23B, 24A, 24B, 25A, 25B, 26A, 26B, 26C, 26A, 26B, 26C, 27A, 27B, 27C, 28A, 28B, 28C, 28D, 29A, 29B, and 29C illustrate various intermediate stages in the manufacturing of nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As discussed in greater detail below, embodiments of the present disclosure describe a dopant implantation process to form p-wells and/or n-wells in a substrate, which may be used to form a transistor (e.g., nano-FETs, fin field effect transistors (FinFETs), planar transistors, or the like). The techniques described herein include using hard implantation masks in implanting the p-wells and/or n-wells. The hard implantation masks may prevent or reduce shrinkage in a high temperature process and can improve the dopant profile of the p-wells and/or n-wells in the lateral direction, thereby improving the junction of neighboring p-wells and n-wells, which may be desirable for transistors with small critical dimensions of p-wells and n-wells. In some embodiments, the materials of the hard masks may also form alignment marks with or without dopants therein, which may provide the alignment marks various adjustable characteristics that can be sensitive to particular processing equipment. Embodiments are described below in a particular context, a die comprising nano-FETs. Various embodiments may be applied, however, to dies comprising other types of transistors, such as FinFETs, planar transistors, or the like, in lieu of or in combination with the nano-FETs.

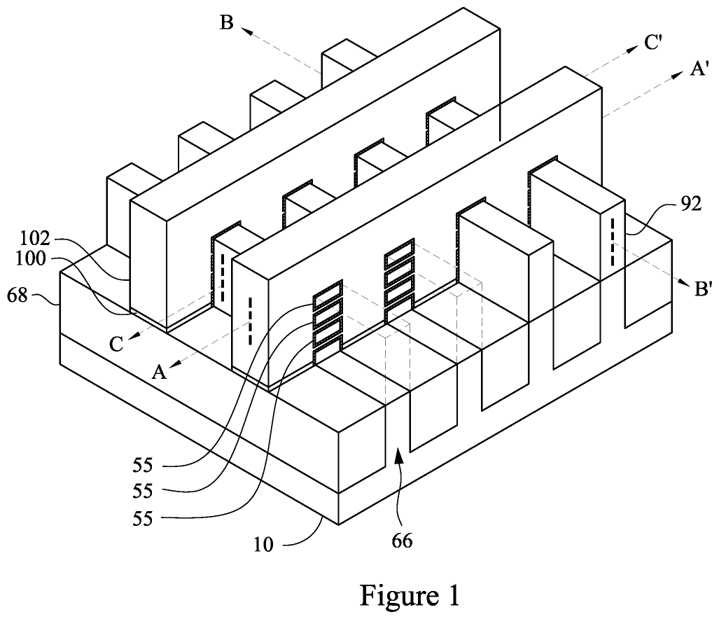

FIG. 1 illustrates an example of nano-FETs (e.g., nanosheet FETs, or the like) in a three-dimensional view, in accordance with some embodiments. The nano-FETs comprise nanostructures 55 (e.g., nanosheets or the like) over fins 66 on a substrate 10 (e.g., a semiconductor substrate), wherein the nanostructures 55 act as channel regions for the nano-FETs. The nanostructures 55 may include p-type nanostructures, n-type nanostructures, or a combination thereof. Isolation regions 68 are disposed between adjacent fins 66, which may protrude above and from between neighboring isolation regions 68. Although the isolation regions 68 are described/illustrated as being separate from the substrate 10, as used herein, the term “substrate” may refer to the semiconductor substrate alone or a combination of the semiconductor substrate and the isolation regions. Additionally, although a bottom portion of the fins 66 are illustrated as being single, continuous materials with the substrate 10, the bottom portion of the fins 66 and/or the substrate 10 may comprise a single material or a plurality of materials. In this context, the fins 66 refer to the portion extending between the neighboring isolation regions 68.

Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is substantially perpendicular to cross-section A-A′ and is substantially parallel to a longitudinal axis of a fin 66 of the nano-FET and in a direction of, for example, a current flow between the epitaxial source/drain regions 92 of the nano-FET, within process variations. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in other devices, such as planar FETs or FinFETs.

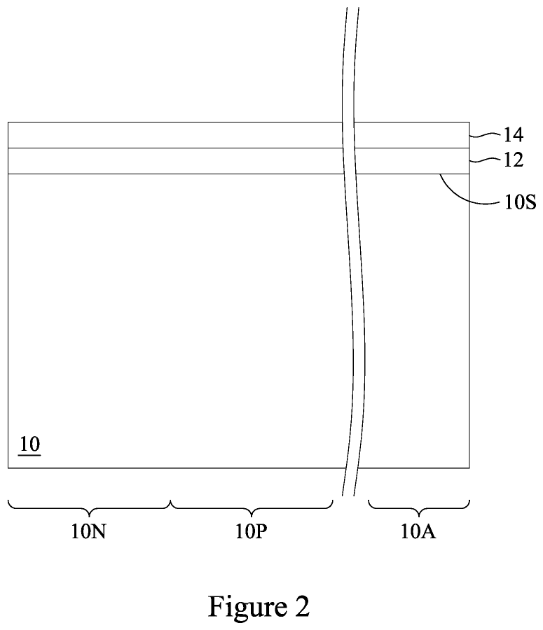

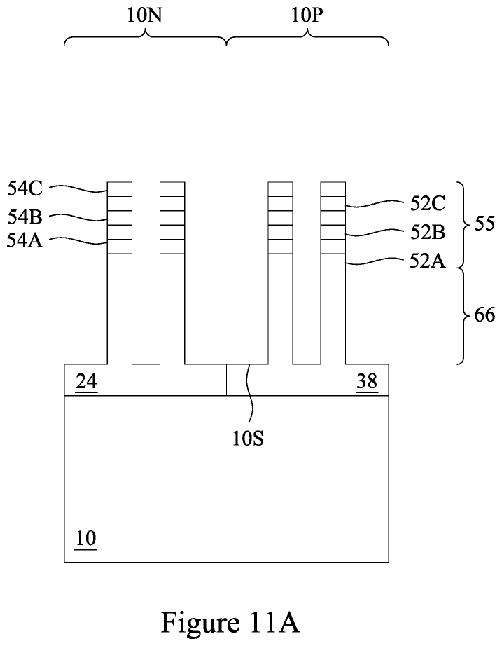

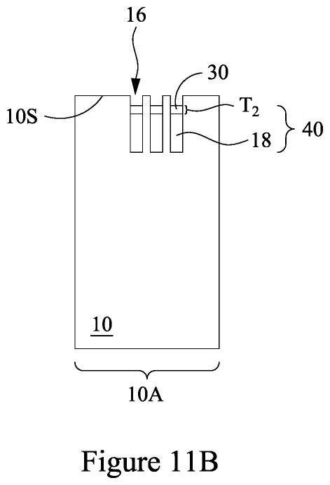

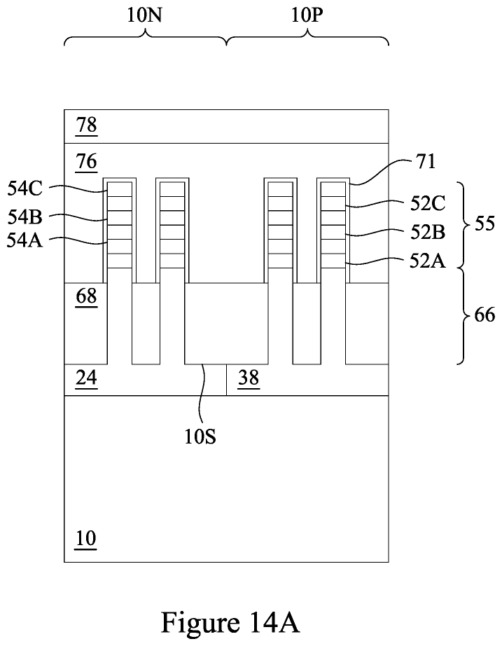

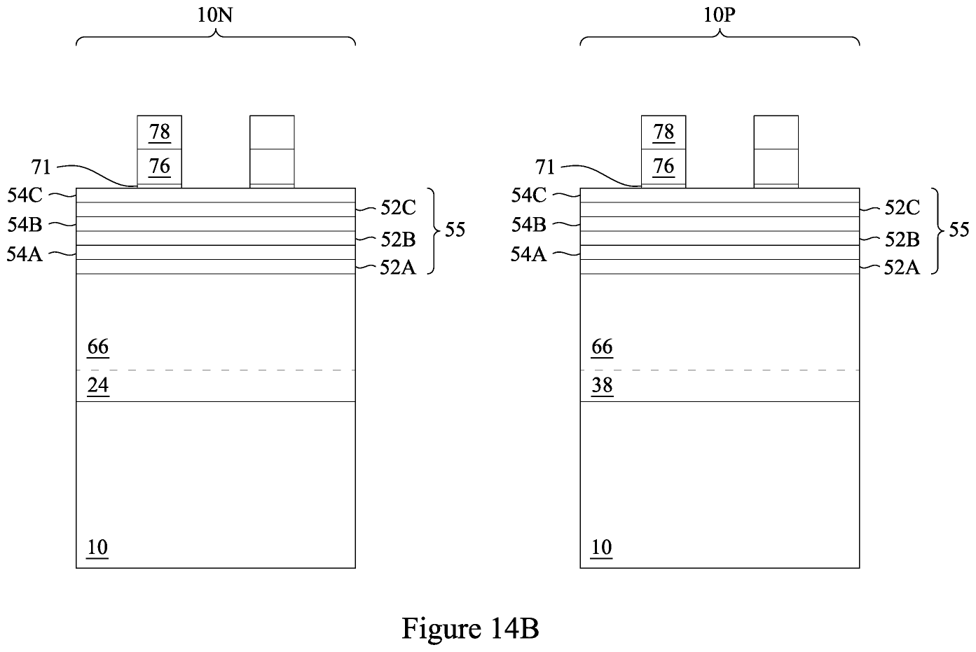

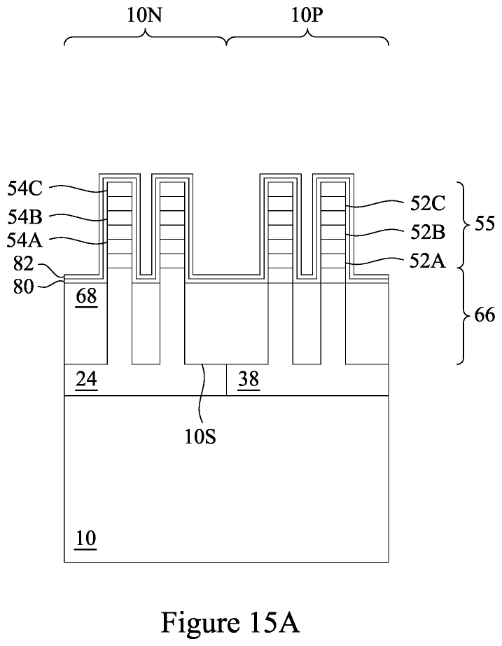

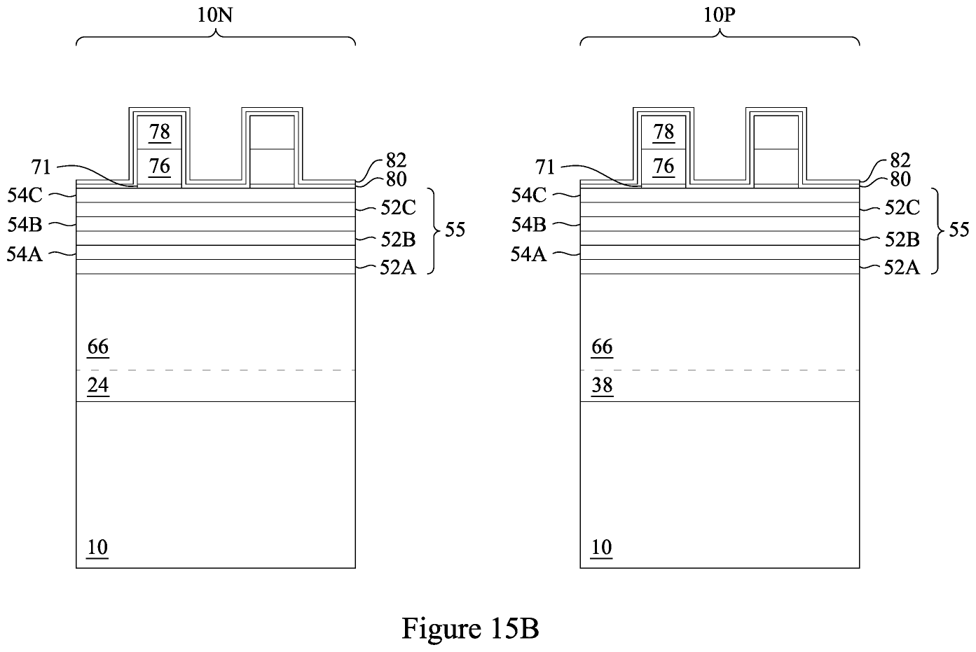

FIG. 2 through 29C illustrate various intermediate stages in the manufacturing of nano-FETs, in accordance with some embodiments. FIGS. 2, 3A, 4, 5, 6, 7, 8, 9, 10, 11A, 12A, 13, 14A, 21A, 22A, 23A, 24A, 25A, 26A, 27A, 28A, and 29A illustrate reference cross-section A-A′ illustrated in FIG. 1. FIGS. 14B, 15B, 16B, 17B, 18B, 19B, 19C, 20B, 20D, 21B, 22B, 23B, 24B, 25B, 26B, 27B, 28B, and 29B illustrate reference cross-section B-B′ illustrated in FIG. 1. FIGS. 15A, 16A, 17A, 18A, 19A, 20A, 20C, 21C, 26C, 27C, 28C, and 29C illustrate reference cross-section C-C′ illustrated in FIG. 1. FIGS. 11B, 12B, and 28D illustrate reference a cross-section that is parallel to reference cross-section A-A′ or B-B′ albeit in a different portion of the structure, such as a portion where an alignment mark is formed.

FIGS. 2 to 9 illustrate methods of forming wells and alignment marks in a substrate, in accordance with some embodiments. Additional processing is contemplated by the present disclosure. Referring first to FIG. 2, the substrate 10 with a mask layer 12 formed over substrate 10 are shown in accordance with some embodiments. The substrate 10 may be a semiconductor substrate, such as a bulk semiconductor, a semiconductor-on-insulator (SOI) substrate, or the like. The substrate 10 may be a wafer, such as a silicon wafer. FIG. 2 and the subsequent figures illustrate a portion of a wafer to better illustrate features of some embodiments. Similar structures and processes may be applied over larger portions of the wafer. Generally, an SOI substrate is a layer of a semiconductor material formed on an insulator layer. The insulator layer may be, for example, a Buried Oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 10 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In some embodiments, the mask layer 12 may include silicon oxide. The mask layer 12 may be formed by oxidizing a surface layer of the substrate 10 or any deposition methods such as using spin-on-coating, chemical vapor deposition (CVD), plasma-enhanced CVD (PECVD), atomic layer deposition (ALD), or the like. The mask layer 12 may include silicon oxide or other suitable materials. In some embodiments, the mask layer 12 protects or reduces the underlying substrate 10 from being damaged by subsequent implant processes. In some embodiments, the mask layer 12 can be omitted.

In some embodiments, the substrate 10 includes an n-type region 10N, a p-type region 10P, and an alignment mark region 10A. The n-type region 10N may be a region for fabricating n-type metal-oxide-semiconductor (NMOS) devices. The p-type region 10P may be a region for fabricating p-type metal-oxide-semiconductor (PMOS) devices. The alignment mark region 10A may be a region for fabricating alignment marks. The alignment marks that may be used to align the substrate 10 (e.g., a wafer) to a suitable direction or a suitable location, in the manufacturing processes.

A mask layer 14 having a pattern for alignment marks is formed over the mask layer 12, in accordance with some embodiments. In accordance with some embodiments, the mask layer 14 may use spin-on-coating, chemical vapor deposition (CVD), plasma-enhanced CVD (PECVD), atomic layer deposition (ALD), physical vapor deposition (PVD), or the like. The mask layer 14 may include silicon nitride, silicon oxynitride, titanium nitride, silicon carbide, silicon oxide, a combination thereof, or the like. In some embodiments, the patterning of the mask layer 14 includes suitable photolithography and etch techniques.

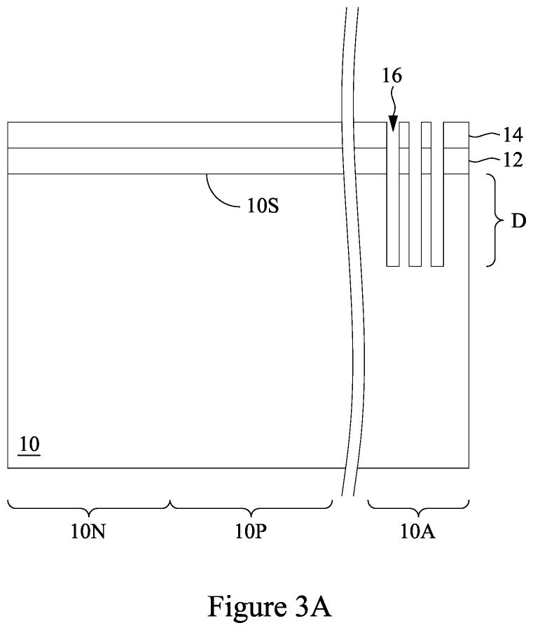

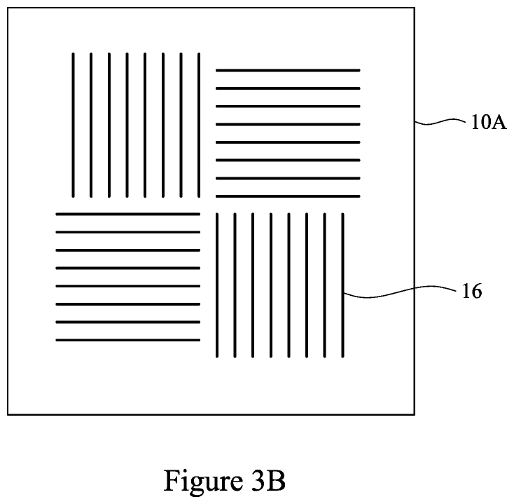

Once the mask layer 14 has been formed, an etching process may be performed to etch the mask layer 12 and the substrate 10 through the mask layer 14, thereby forming trenches 16 in the substrate 10 and the mask layer 12, as shown in FIG. 3A. In some embodiments, the depth D of the trenches 16 in the substrate is in a range from about 100 nm to about 150 nm, such as about 120 nm, beneath a major upper surface 10S of the substrate 10. Each trench 16 may have a width ranging from about 1 μm to about 2 μm, such as about 1.5 μm. The mask layer 14 may be removed after the trenches 16 are formed. In some embodiments, the mask layer 14 is removed by an etching process, such as a dry etch or a wet etch. The trenches and/or any materials formed therein may form an alignment mark. Although only 3 trenches 16 are illustrated in FIG. 3A, the number and the arrangements of trenches 16 are not limited. For example, a top view of the alignment mark region 10A of the substrate 10 is shown in FIG. 3B, in accordance with some embodiments, and other shapes and arrangements of the trenches 16 may also be applied.

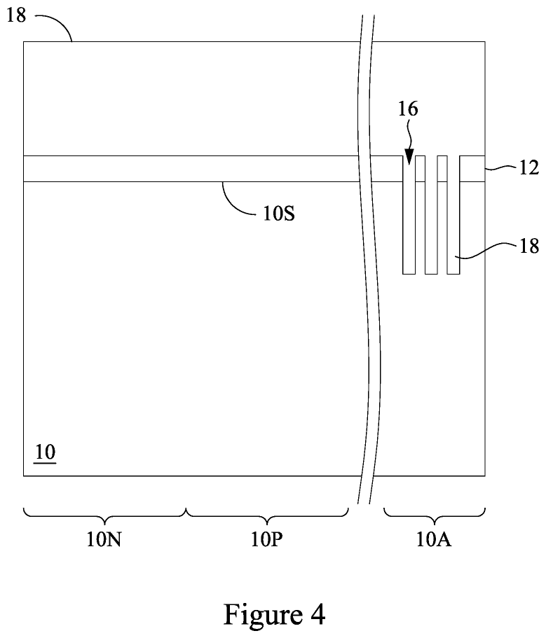

Referring to FIG. 4, an implantation mask 18 is formed over the mask layer 12 and fills the trenches 16, in accordance with some embodiments. The implantation mask 18 may be formed of a material capable of substantially blocking ions in an implantation process. For example, the implantation mask 18 may be a hard mask material of sufficient thickness, such as silicon nitride, silicon oxynitride, silicon carbide, a combination thereof, or the like. The implantation mask 18 may be formed by suitable deposition techniques, such as spin-on-coating, chemical vapor deposition (CVD), plasma-enhanced CVD (PECVD), physical vapor deposition (PVD), or the like.

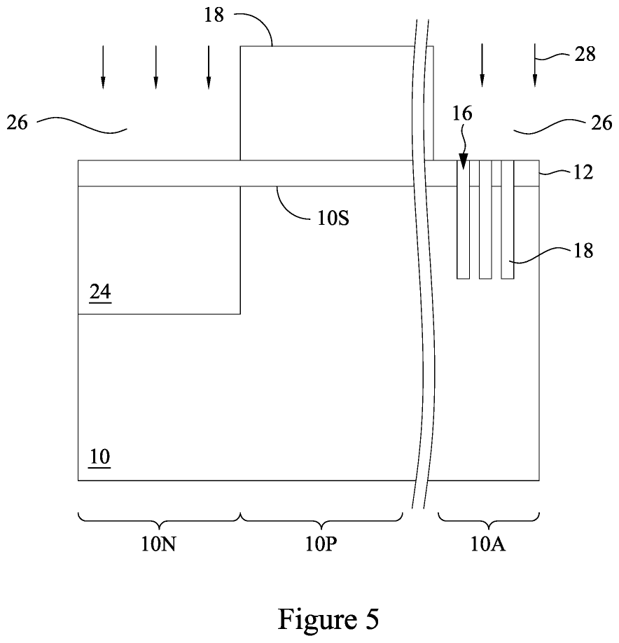

Referring to FIG. 5, the implantation mask 18 may be patterned to form openings 26 in the implantation mask 18. The openings 26 may expose the n-type region 10N and the alignment mark region 10A. Patterning the implantation mask 18 may include suitable photolithography and etching techniques. For example, one or more photoresist layers (not shown) may be deposited over the implantation mask 18 and patterned by suitable photolithography techniques. An etching process is then performed on the implantation mask 18 through the patterned photoresist layer to form the openings 26 in the implantation mask 18. An acceptable process, such as an ashing process, may be used to remove the photoresist layer.

Once the implantation mask 18 is formed, one or more p-type ion implantation processes 28 are performed to lightly dope the substrate 10, thereby forming one or more p-wells 24 in the substrate 10, in accordance with some embodiments. The p-wells 24 may provide active regions in the substrate 10 for fabricating NMOS devices. In some embodiments, the material of the implantation mask 18 in the trenches 16 and the substrate 10 in the alignment mark region 10A are also doped with the p-type dopant. The p-type dopant may include boron, indium, the like, or combinations thereof. In some embodiments, the p-type ion implantation processes 28 include multiple blanket implantation processes to achieve the desired dopant profile. For example, a first p-type ion implantation may be performed using an energy in a range from about 180 keV to about 240 keV with a dose of about 1×10¹² atoms/cm² to about 1×10¹³ atoms/cm². The first p-type implantation process may provide p-type regions in the substrate that may act as deep p-wells (not separately shown). A second p-type ion implantation may be performed using energy in a range from about 1 keV to about 100 keV with a dose of about 1×10¹³ atoms/cm² to about 1×10¹⁴ atoms/cm². The second p-type implantation process may provide p-type regions in the substrate that act as shallow p-wells (not separately shown). Although only two p-type ion implantation processes are described above as an example, more p-type ion implantations may be applied to achieve the desired dopant profile. The p-type dopant concentration in the p-well 24 and the material of the implantation mask 18 may be equal to or less than about 1×10¹⁶ cm⁻³, such as in a range from about 1×10¹⁵ cm⁻³ to about 5×10¹⁵ cm⁻³.

The first and second p-type implantation processes may be hot implantation processes, such as in a temperature of over about 150° C., such as of between about 200° C. and about 450° C. The hot implantation processes may help reduce interstitial defects generated in the substrate 10 during the implantation processes. Unlike a photoresist material, the hard mask material of the implantation mask 18 may not shrink or deform (or at least shrink and/or deform to a significantly lesser extent than does photoresist material) and can hence retain its pattern and critical dimensions after one or more hot implantation processes. The boundary of the p-well 24 in a lateral direction may be therefore precisely controlled with the use of implantation mask 18. An annealing may be performed to repair implantation damage and to activate the implanted impurities. The annealing may be performed at a temperature in a range from about 1000° C. to about 1100° C., such as about 1050° C. for a duration of about 1 second to about 20 seconds, such as about 10 seconds.

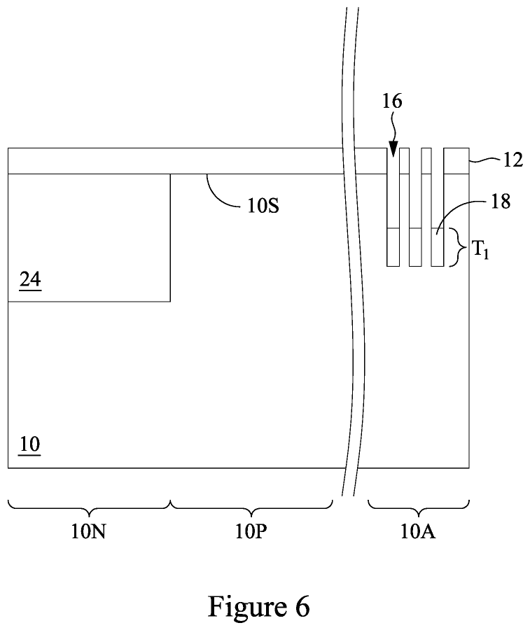

Referring to FIG. 6, once the p-well 24 has been formed, an etching process is performed to remove the implantation mask 18 over the major upper surface 10S of the substrate 10. In some embodiments, the etching process also partially etches the material of the implantation mask 18 in trenches 16. The implantation mask 18 may not be completely etched because of loading effects. For example, the remaining material of the implantation mask 18 in the trenches 16 may have a thickness T₁ of about 0.5 μm to about 1 μm. The etching process may be an acceptable etching process, such as a wet etch, a dry etch, or a combination thereof. The etching process may be a timed etching process, and the recessing depth or the thickness T₁ may be controlled by the time of the etching process.

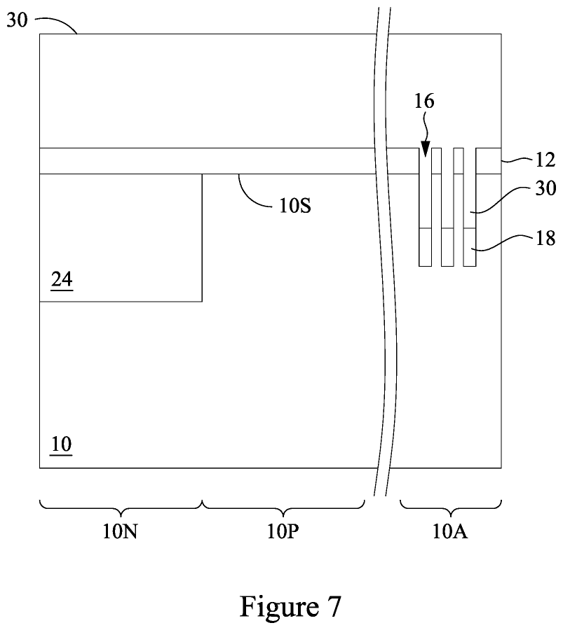

Referring to FIG. 7, an implantation mask 30 is formed over the mask layer 12 and fills the trenches 16, in accordance with some embodiments. For example, a portion of the material of the implantation mask 30 may be in the trenches 16 and above the material of the implantation mask 18. The implantation mask 30 is formed of a material capable of substantially blocking ions in an implantation process. The implantation mask 30 may be a hard mask material of sufficient thickness, such as silicon oxide, silicon nitride, silicon oxynitride, silicon carbide, a combination thereof, or the like. The implantation mask 30 may be a material different from the implantation mask 18 although a similar material may be used. The implantation mask 30 may be formed by suitable deposition techniques, such as spin-on-coating, chemical vapor deposition (CVD), plasma-enhanced CVD (PECVD), physical vapor deposition (PVD), or the like.

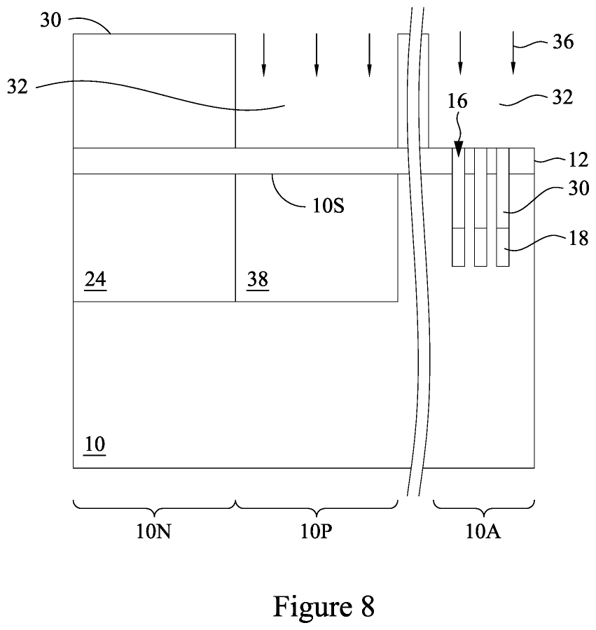

Referring to FIG. 8, the implantation mask 30 is patterned to form openings 32 in the implantation mask 30, in accordance with some embodiments. The openings 32 may expose the p-type region 10P and the alignment mark region 10A. Patterning the implantation mask 30 may include suitable photolithography and etching techniques. For example, one or more photoresist layers (not shown) may be deposited over the implantation mask 30 and patterned by suitable photolithography techniques. An etching process is then performed on the implantation mask 30 through the patterned photoresist layer to form the openings 32 in the implantation mask 30. An acceptable process, such as an ashing process, may be used to remove the photoresist layer.

Once the implantation mask 30 has been formed, one or more n-type ion implantation processes 36 are performed to lightly dope the substrate 10, thereby forming one or more n-wells 38 in the substrate 10, in accordance with some embodiments. The n-wells 38 may provide active regions in the substrate 10 for fabricating PMOS devices. In some embodiments, the material of the implantation mask 30 in the trenches 16 and the substrate 10 in the alignment mark region 10A are also doped with the n-type dopant. The n-type dopant may include phosphorous, arsenic, antimony, the like, or combinations thereof. In some embodiments, the n-type ion implantation processes 36 include multiple blanket implantation processes to achieve the desired dopant profile. For example, a first n-type ion implantation may be performed using energy in a range from about 180 keV to about 240 keV with a dose of about 1×10¹² atoms/cm² to about 1×10¹³ atoms/cm². The first n-type implantation process may provide n-type regions in the substrate that may act as deep n-wells (not separately shown). A second n-type ion implantation may be performed using an energy in a range from about 1 keV to about 150 keV with a dose of 1×10¹³ atoms/cm² to about 1×10¹⁴/cm². The second n-type implantation process may provide n-type regions in the substrate that may act as shallow n-wells (not separately shown). Although only two n-type ion implantation processes are described above as an example, more n-type ion implantation may also be applied to achieve the desired dopant profile. The n-type dopant concentration in the n-well 38, the material of implantation mask 18 in the trenches 16, and the material of implantation mask 30 in the trenches 16 may be equal to or less than 1×10¹⁶ cm⁻³, such as in a range from about 1×10¹⁵ cm⁻³ to about 5×10¹⁵ cm⁻³. In some embodiments, the n-well 38 abuts the p-well 24.

The first and second n-type implantation processes may be hot implantation processes, such as in a temperature of over about 150° C., such as of between about 200° C. and about 450° C. The hot implantation processes may help reduce interstitial defects generated in the substrate 10 resulting from the implantation processes. Unlike a photoresist material, the hard mask material of the implantation mask 30 may not shrink or deform (or at least shrink and/or deform to a significantly lesser extent than does photoresist material) and hence can retain its pattern and critical dimensions after one or more hot implantation processes. The boundary of the n-well 38 in a lateral direction may be precisely controlled with the use of implantation mask 30, which may help reduce overlapping of neighboring p-well 24 and n-well 38. Junction leakage may be thus reduced. An annealing may be performed to repair implantation damage and to activate the implanted impurities. The annealing may be performed at a temperature in a range from about 1000° C. to about 1100° C., such as about 1050° C. for a duration of about 1 second to about 20 seconds, such as about 10 seconds.

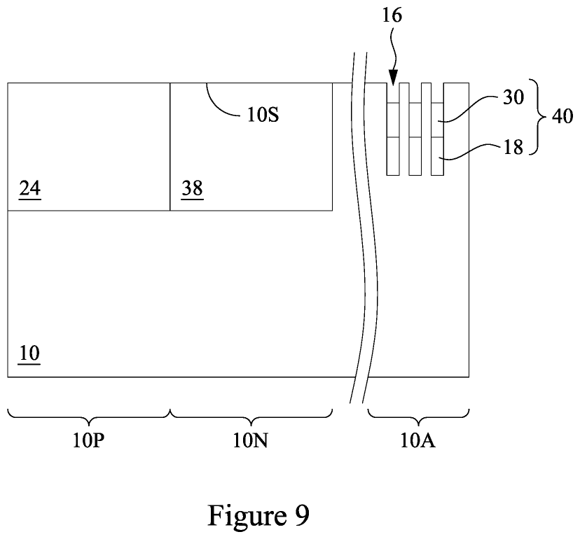

Referring to FIG. 9, once the n-well 38 has been formed, at least one etching process is performed to remove the implantation mask 30 over the major upper surface 10S of the substrate 10, and the mask layer 12. For example, the implantation mask 30 and the mask layer 12 may be removed by separate etching process. Alternatively, the implantation mask 30 and the mask layer 12 may be removed together by a single etching process when the implantation mask 30 and the mask layer 12 are a similar material. In some embodiments, the material of implantation mask 30 in the trenches 16 are also partially or completely removed by the etching process. Any remaining material of the implantation mask 30 will be level with or below the major upper surface 10S of the substrate 10. The etching process may be an acceptable etching process, such as a wet etch, a dry etch, or a combination thereof. The etching process may be a timed etching process, and the recessing depth or the remaining thickness of the implantation mask 30 in the trenches 16 may be controlled by the time of the etching process.

The materials of the implantation mask 18 and the implantation mask 30 in the trenches 16 form an alignment mark 40 that may be used to align the wafer in the subsequent processes. A lower portion of the alignment mark 40 may be formed of the material of the implantation mask 18, and an upper portion of the alignment mark 40 may be formed of the material of the implantation mask 30. In some embodiments, the lower portion of the alignment mark 40 is doped with both p-type and n-type dopants, and the upper portion of the alignment mark 40 is doped with the n-type dopant. Alternatively, in some embodiments, the alignment mark 40 is doped with only one kind of dopant. For example, the openings 26 of the implantation mask 18 may not expose the alignment mark region 10A, so the alignment mark 40 is doped with the n-type dopant only. Alternatively, the openings 32 of the implantation mask 30 may not expose the alignment mark region 10A, so the lower portion of the alignment mark 40 is doped with the p-type dopant only, and the upper portion of the alignment mark 40 is non-doped. In some embodiments, the substrate 10 in the alignment mark region 10A adjacent to the alignment mark 40 may also be doped with the same type and concentration of dopants as the alignment mark 40. FIGS. 2 through 9 show forming the p-well 24 prior to forming the n-well 38 for illustrative purposes. In some embodiments, the n-well 38 is formed prior to the p-well 24, and the conductivity types of the dopants in the alignment mark 40 are opposite to the embodiments as discussed above. For example, the lower portion of the alignment mark 40 may be doped with both the n-type dopant and p-type dopant or doped with only the n-type dopant, and the upper portion of alignment mark 40 may be doped with only the p-type dopant or non-doped.

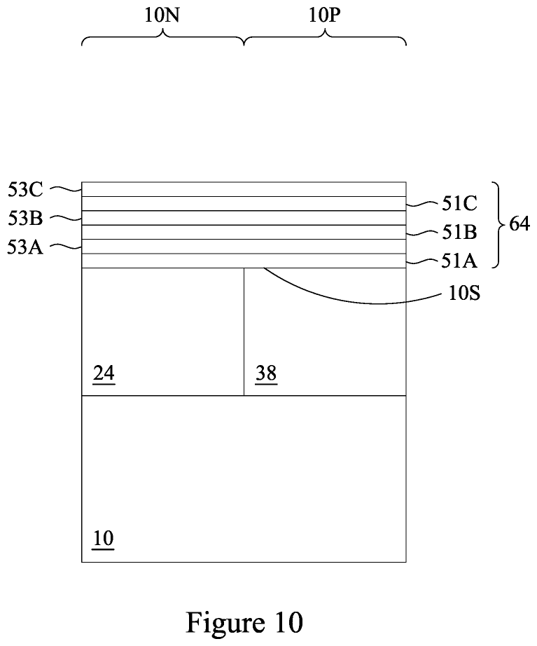

Although FIGS. 2 to 9 illustrate the alignment mark 40 in the reference cross-section A-A′, the alignment mark 40 may be formed in other locations, such as in the cross-section B-B′ or C-C′ or in a cross-section parallel to the cross-section A-A′ or B-B′. In addition, although the alignment mark 40 is not illustrated in the nano-FET device illustrated in FIG. 1, the alignment mark 40 may be in device regions of the substrate 10 and remain in the IC chips after the substrate 10 is scribed, or alternatively the alignment marks may be in scribe regions or other non-device regions of the substrate 10 and may not exist in the IC chips after the substrate 10 is scribed. For illustrative purposes, in the subsequent figures (e.g., starting from FIG. 10), the alignment mark region 10A is individually shown such as in FIGS. 11B, 12B, and 28D and not separately shown in figures showing the reference cross-section A-A′.

Additional process steps may be performed to manufacture the nano-FETs. Referring to FIG. 10, a multi-layer stack 64 is formed over the substrate 10. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the second semiconductor layers 53 will be removed and the first semiconductor layers 51 will be patterned to form channel regions of nano-FETs in the p-type region 10P. Also, the first semiconductor layers 51 will be removed and the second semiconductor layers 53 will be patterned to form channel regions of nano-FETs in the n-type region 10N. Nevertheless, in some embodiments the first semiconductor layers 51 may be removed and the second semiconductor layers 53 may be patterned to form channel regions of nano-FETs in the n-type region 10N, and the second semiconductor layers 53 may be removed and the first semiconductor layers 51 may be patterned to form channel regions of nano-FETs in the p-type region 10P.

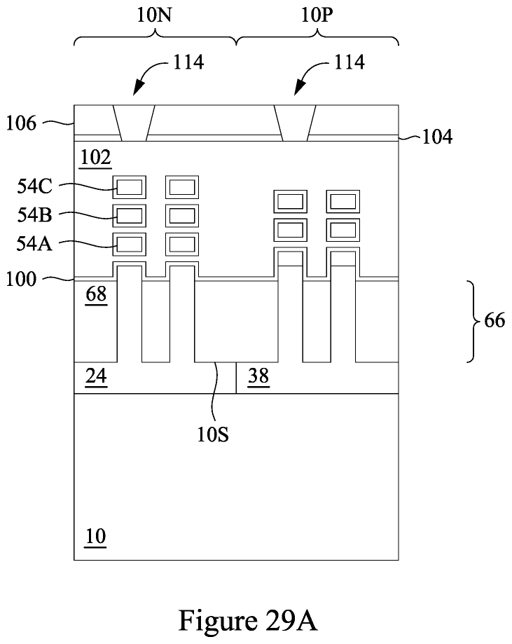

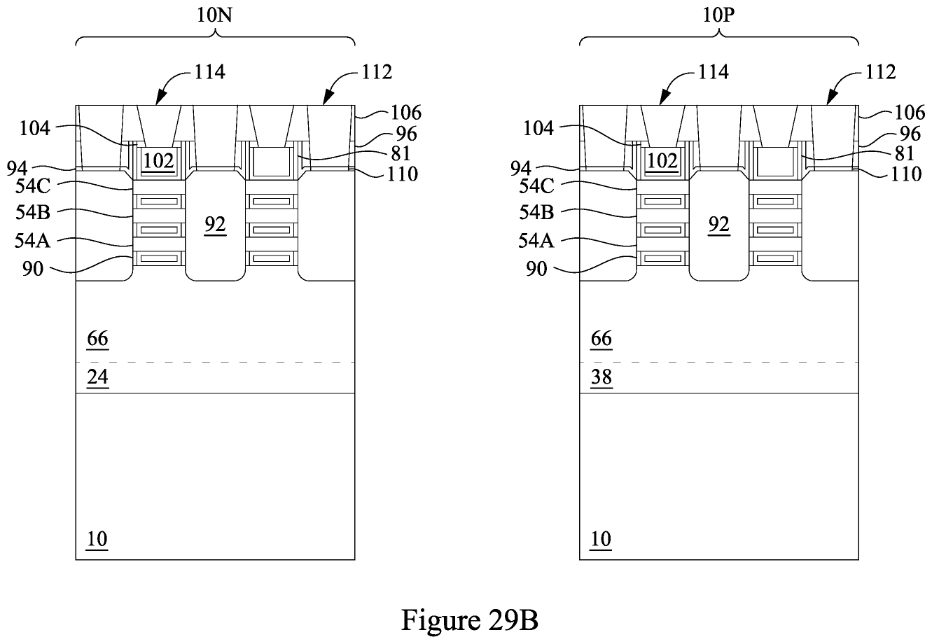

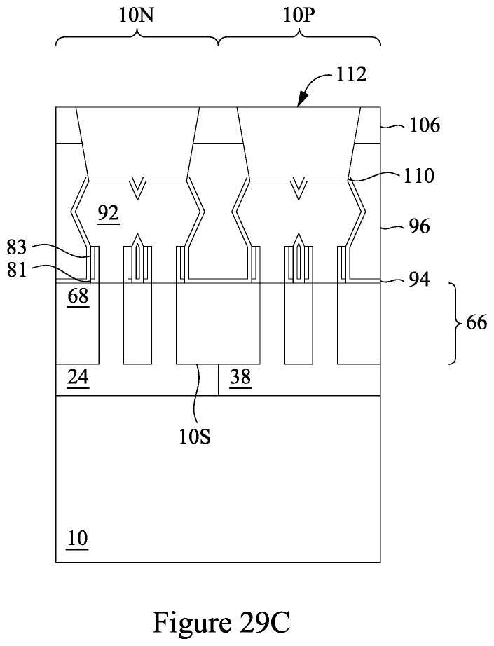

In some embodiments, the first semiconductor layers 51 may be removed and the second semiconductor layers 53 may be patterned to form channel regions of nano-FETS in both the n-type region 10N and the p-type region 10P. In other embodiments, the second semiconductor layers 53 may be removed and the first semiconductor layers 51 may be patterned to form channel regions of non-FETs in both the n-type region 10N and the p-type region 10P. In such embodiments, the channel regions in both the n-type region 10N and the p-type region 10P may have a same material composition (e.g., silicon, or the another semiconductor material) and be formed simultaneously. FIGS. 29A-C illustrate a structure resulting from such embodiments where the channel regions in both the p-type region 10P and the n-type region 10N comprise silicon, for example.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium, or the like, and the second semiconductor layers 53 may be formed of a second semiconductor material suitable for n-type nano-FETs, such as silicon, silicon carbon, or the like. The multi-layer stack 64 is illustrated as having a bottommost semiconductor layer suitable for p-type nano-FETs for illustrative purposes. In some embodiments, multi-layer stack 64 may be formed such that the bottommost layer is a semiconductor layer suitable for n-type nano-FETs. The first semiconductor layers 51 and the second semiconductor layers 53 may be doped in situ or using one or more implant processes.

The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material in the n-type region 10N, thereby allowing the second semiconductor layers 53 to be patterned to form channel regions of n-type nano-FETs. Similarly, the second semiconductor layers 53 of the second semiconductor material may be removed without significantly removing the first semiconductor layers 51 of the first semiconductor material in the p-type region 10P, thereby allowing the first semiconductor layers 51 to be patterned to form channel regions of p-type nano-FETs.

Referring now to FIG. 11A, fins 66 are formed in the regions of substrate 10 and nanostructures 55 are formed in the multi-layer stack 64, in accordance with some embodiments. The fins 66 protrude from a major upper surface 10S of the substrate 10 and the height of the fins 66 is in a range from about 50 nm to about 70 nm. In some embodiments, the nanostructures 55 and the fins 66 may be formed in the multi-layer stack 64 and the substrate 10, respectively, by etching trenches in the multi-layer stack 64 and the substrate 10. In some embodiments, referring to FIG. 11B, the alignment mark 40 may be also recessed with the substrate 10 while forming the fins 66 in the p-type region 10P and the n-type region 10B. For example, at least a portion of the material of the implantation mask 30 is etched. Accordingly, the top surface of the alignment mark 40 may be below or even with the major upper surface 10S of the substrate 10. The remaining material of the implantation mask 30 in the trenches 16 may have a thickness T₂ thinner than the thickness T₁ of the material of the implantation mask 18 in the trenches 16. For example, the thickness T₂ may be smaller than about 0.5 μm.

The etching process to form the fins 66 and the nanostructures 55 may be any acceptable etching process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as nanostructures 55. FIG. 11A illustrates that two fins are formed in each of the n-type region 10N and the p-type region 10P, in other embodiments a different number of fins may be formed in each region.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 11A illustrates the fins 66 in the n-type region 10N and the p-type region 10P as having substantially equal widths for illustrative purposes. In some embodiments, widths of the fins 66 in the n-type region 10N may be greater or thinner than the fins 66 in the p-type region 10P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 10. In such embodiments, each of the nanostructures 55 may have a different width and be trapezoidal in shape.

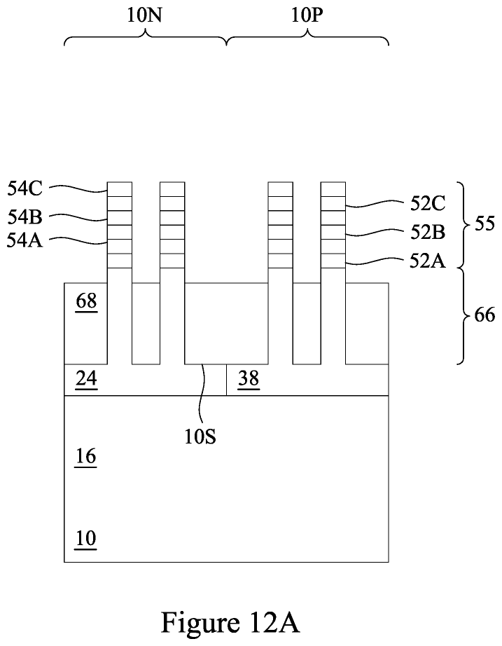

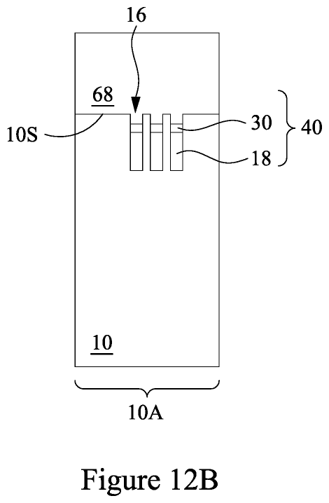

In FIGS. 12A and 12B, shallow trench isolation (STI) regions 68 are formed adjacent the fins 66 and above the alignment mark 40, in accordance with some embodiments. The STI regions 68 may be formed by depositing an insulation material over the substrate 10, the fins 66, and nanostructures 55, between adjacent fins 66, and above the alignment mark 40. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An annealing process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along the major upper surface 10S of the substrate 10, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 10N and the p-type region 10P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

In some embodiments, referring to FIG. 12B, the STI regions 68 includes a portion filling the trenches 16 and covering the alignment mark 40. The alignment mark 40 will be covered by the STI regions 68 and not substantially altered in subsequent processes. In some embodiments, the material of the implantation mask 30 and the STI regions 68 are both formed of oxide, and the implantation mask 30 has a higher density than the STI regions 68 when the implantation mask 30 is formed by PECVD, and the STI regions 68 is formed by FCVD.

The process described above with respect to FIGS. 10, 11A, and 12A is just one example of how the fins 66 and the nanostructures 55 may be formed. In some embodiments, the fins 66 and/or the nanostructures 55 may be formed using a mask and an epitaxial growth process. For example, a dielectric layer can be formed over the major upper surface 10S of the substrate 10, and trenches can be etched through the dielectric layer to expose the underlying substrate 10. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments, where epitaxial structures are epitaxially grown, the epitaxially grown materials may be in situ doped during growth, or doped through one or more implantation processes.

Additionally, the first semiconductor layers 51 (and resulting nanostructures 52) and the second semiconductor layers 53 (and resulting nanostructures 54) are illustrated and discussed herein as comprising the same materials in the p-type region 10P and the n-type region 10N for illustrative purposes only. As such, in some embodiments one or both of the first semiconductor layers 51 and the second semiconductor layers 53 may be different materials or formed in a different order in the p-type region 10P and the n-type region 10N.

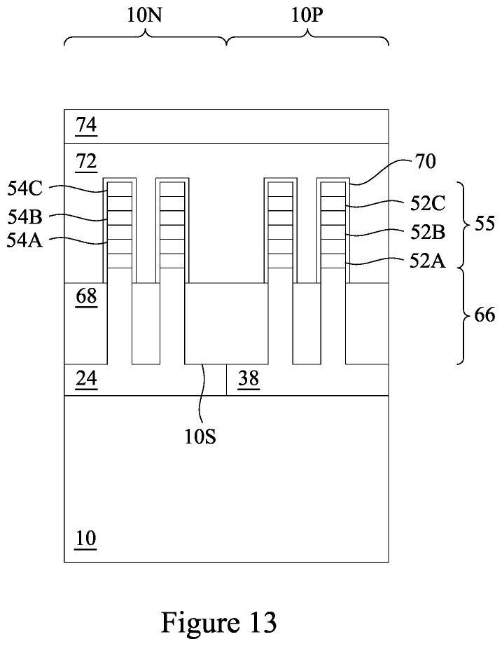

In FIG. 13, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 10N and the p-type region 10P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 14A through 26C illustrate various additional steps in the manufacturing of embodiment devices. In FIGS. 14A and 14B, the mask layer 74 (see FIG. 13) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

In FIGS. 15A and 15B, a first spacer layer 80 and a second spacer layer 82 are formed over the structures illustrated in FIGS. 14A and 14B, respectively. The first spacer layer 80 and the second spacer layer 82 will be subsequently patterned to act as spacers for forming self-aligned source/drain regions. In FIGS. 15A and 15B, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implantations for lightly doped source/drain (LDD) regions (not separately illustrated) may be performed. In embodiments with different device types, a mask, such as a photoresist, may be formed over the n-type region 10N, while exposing the p-type region 10P, and appropriate type (e.g., p-type) impurities may be implanted into the exposed fins 66 and nanostructures 55 in the p-type region 10P. The mask may then be removed. Subsequently, a mask, such as a photoresist, may be formed over the p-type region 10P while exposing the n-type region 10N, and appropriate type impurities (e.g., n-type) may be implanted into the exposed fins 66 and nanostructures 55 in the n-type region 10N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atom/cm³ to about 1×10¹⁹ atom/cm³. An annealing may be used to repair implantation damage and to activate the implanted impurities.

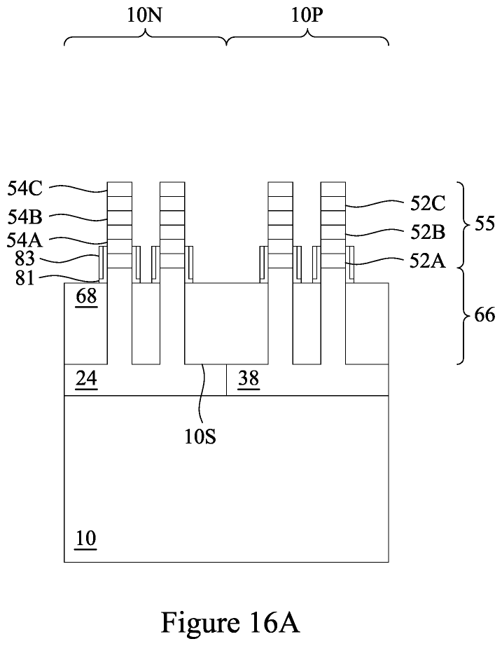

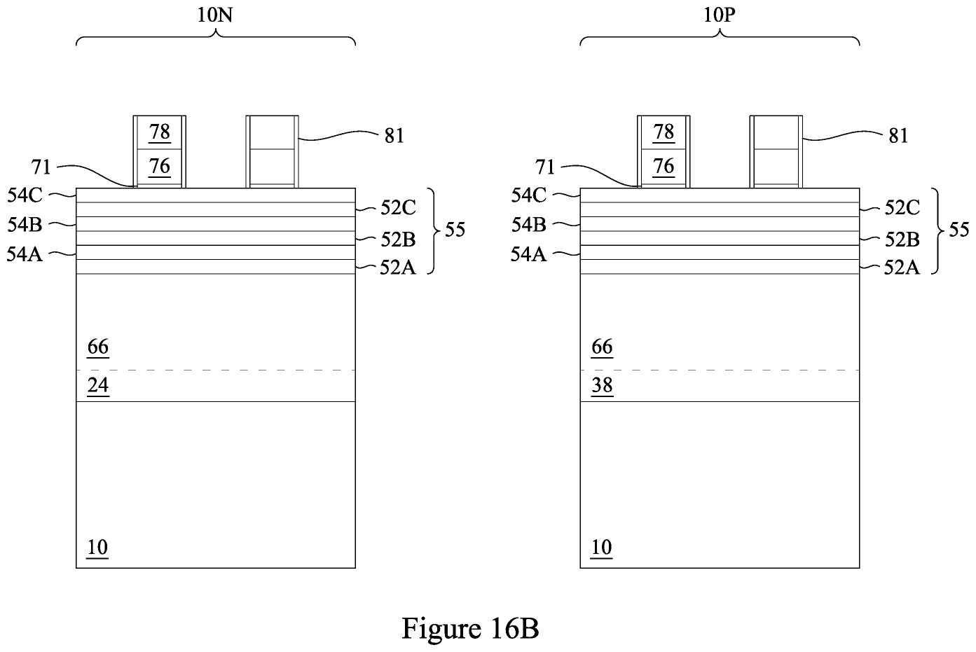

In FIGS. 16A and 16B, the first spacer layer 80 and the second spacer layer 82 are etched to form first spacers 81 and second spacers 83. As will be discussed in greater detail below, the first spacers 81 and the second spacers 83 act to self-aligned subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etching process wherein the first spacer layer 80 acts as an etch stop layer, wherein remaining portions of the second spacer layer 82 form second spacers 83 as illustrated in FIG. 16A. Thereafter, the second spacers 83 acts as a mask while etching exposed portions of the first spacer layer 80, thereby forming first spacers 81 as illustrated in FIG. 16A.

As illustrated in FIG. 16A, the first spacers 81 and the second spacers 83 are disposed on sidewalls of the fins 66 and/or nanostructures 55. As illustrated in FIG. 8B, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy dielectric layers 60. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

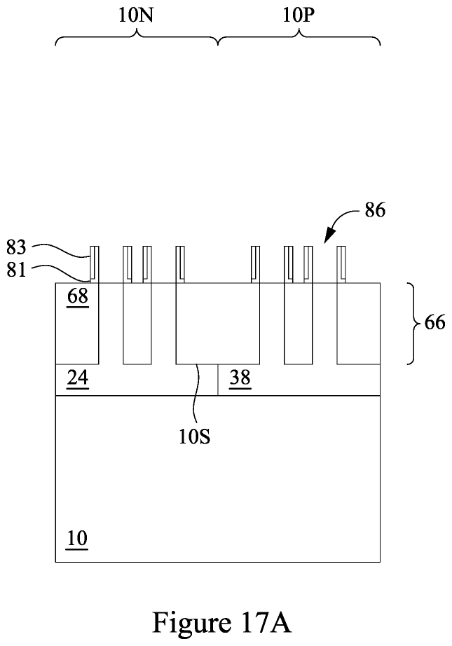

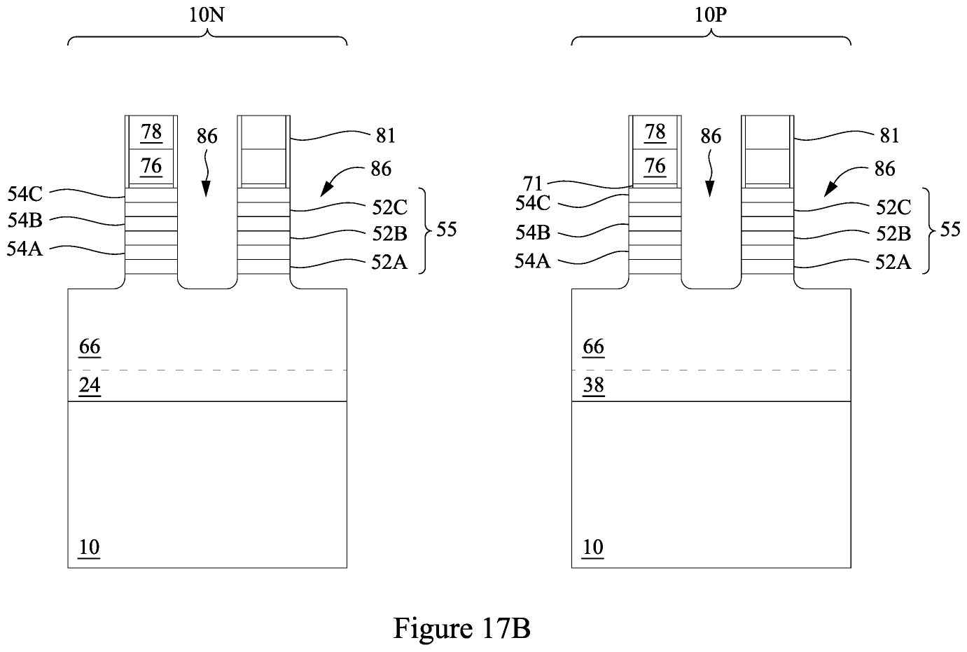

In FIGS. 17A and 17B, first recesses 86 are formed in the fins 66, the nanostructures 55, and the substrate 10, in accordance with some embodiments. Epitaxial source/drain regions will be subsequently formed in the first recesses 86. The first recesses 86 may extend through the first nanostructures 52 and the second nanostructures 54, and into the substrate 10. As illustrated in FIG. 17A, top surfaces of the STI regions 68 may be level with bottom surfaces of the first recesses 86. In various embodiments, the fins 66 may be etched such that bottom surfaces of the first recesses 86 are disposed below the top surfaces of the STI regions 68; or the like. The first recesses 86 may be formed by etching the fins 66, the nanostructures 55, and the substrate 10 using anisotropic etching processes, such as RIE, NBE, or the like. The first spacers 81, the second spacers 83, and the masks 78 mask portions of the fins 66, the nanostructures 55, and the substrate 10 during the etching processes used to form the first recesses 86. A single etching process or multiple etching processes may be used to etch each layer of the nanostructures 55 and/or the fins 66. Timed etching processes may be used to stop the etching of the first recesses 86 after the first recesses 86 reach a desired depth.

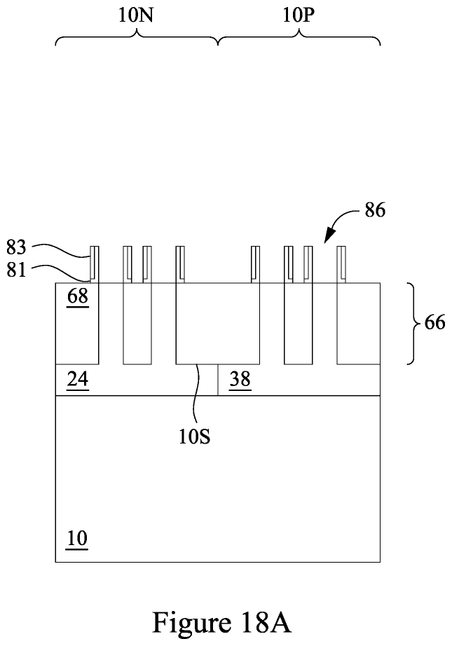

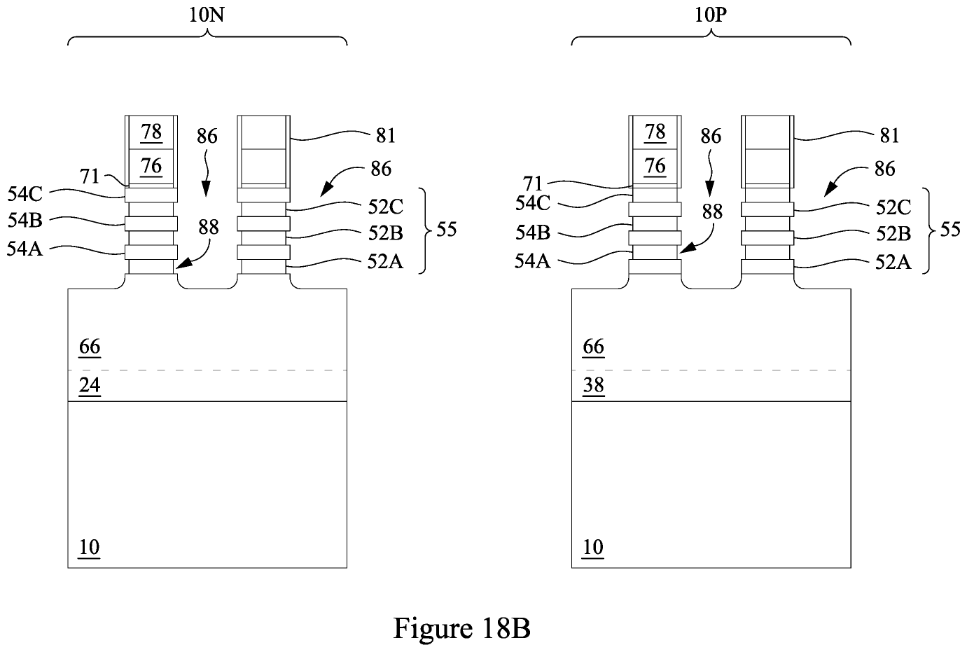

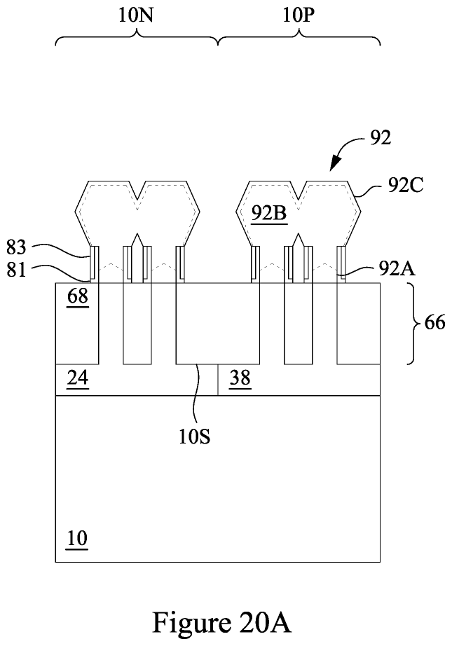

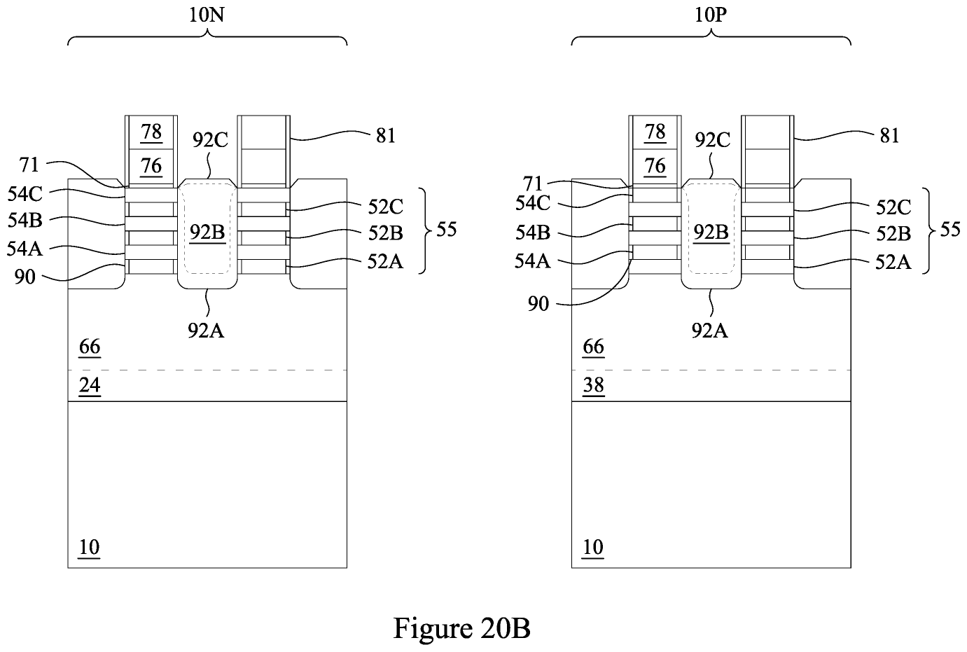

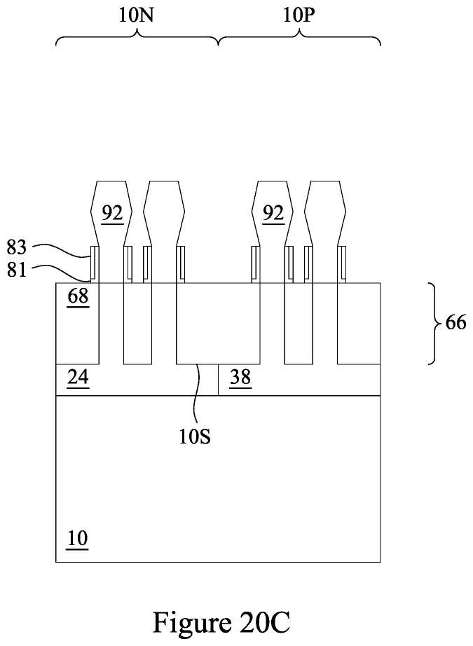

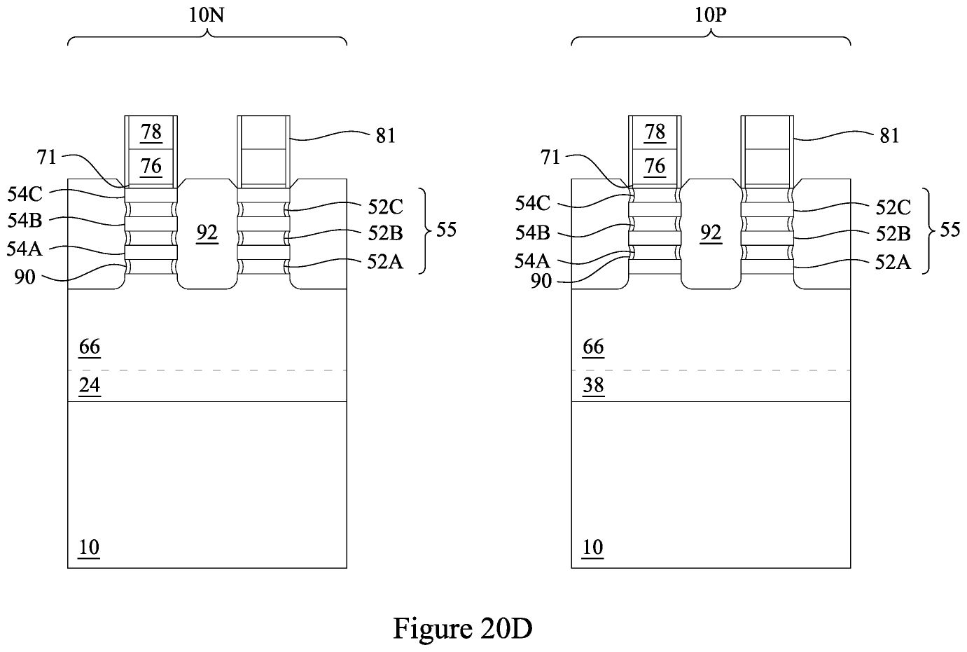

In FIGS. 18A and 18B, portions of sidewalls of the layers of the multi-layer stack 64 formed of the first semiconductor materials (e.g., the first nanostructures 52) exposed by the first recesses 86 are etched to form sidewall recesses 88 in the n-type region 10N, and portions of sidewalls of the layers of the multi-layer stack 56 formed of the second semiconductor materials (e.g., the second nanostructures 54) exposed by the first recesses 86 are etched to form sidewall recesses 88 in the p-type region 10P. Although sidewalls of the first nanostructures 52 and the second nanostructures 54 in sidewall recesses 88 are illustrated as being straight in FIG. 20B, the sidewalls may be concave or convex. The sidewalls may be etched using isotropic etching processes, such as wet etching or the like. The p-type region 10P may be protected using a mask (not shown) while etchants selective to the first semiconductor materials are used to etch the first nanostructures 52 such that the second nanostructures 54 and the substrate 10 remain relatively unetched as compared to the first nanostructures 52 in the n-type region 10N. Similarly, the n-type region 10N may be protected using a mask (not shown) while etchants selective to the second semiconductor materials are used to etch the second nanostructures 54 such that the first nanostructures 52 and the substrate 10 remain relatively unetched as compared to the second nanostructures 54 in the p-type region 10P. In an embodiment in which the first nanostructures 52 include, e.g., SiGe, and the second nanostructures 54 include, e.g., Si or SiC, a dry etching process with tetramethylammonium hydroxide (TMAH), ammonium hydroxide (NH₄OH), or the like may be used to etch sidewalls of the first nanostructures 52 in the n-type region 10N, and a wet or dry etching process with hydrogen fluoride, another fluorine-based etchant, or the like may be used to etch sidewalls of the second nanostructures 54 in the p-type region 10P.

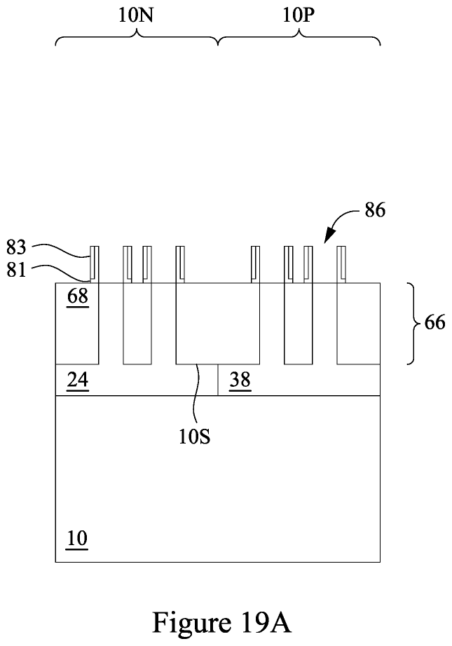

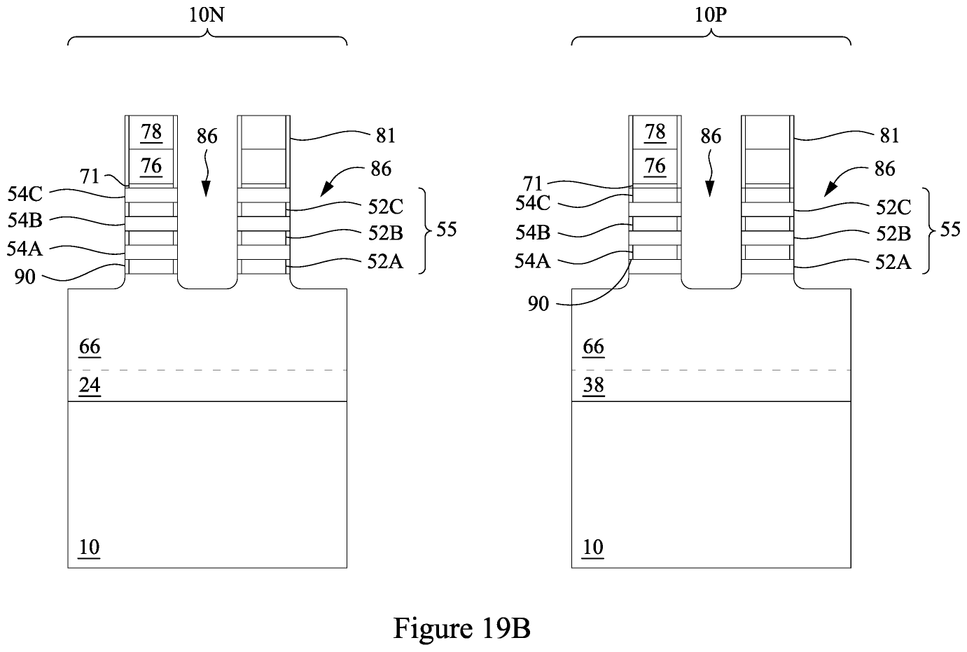

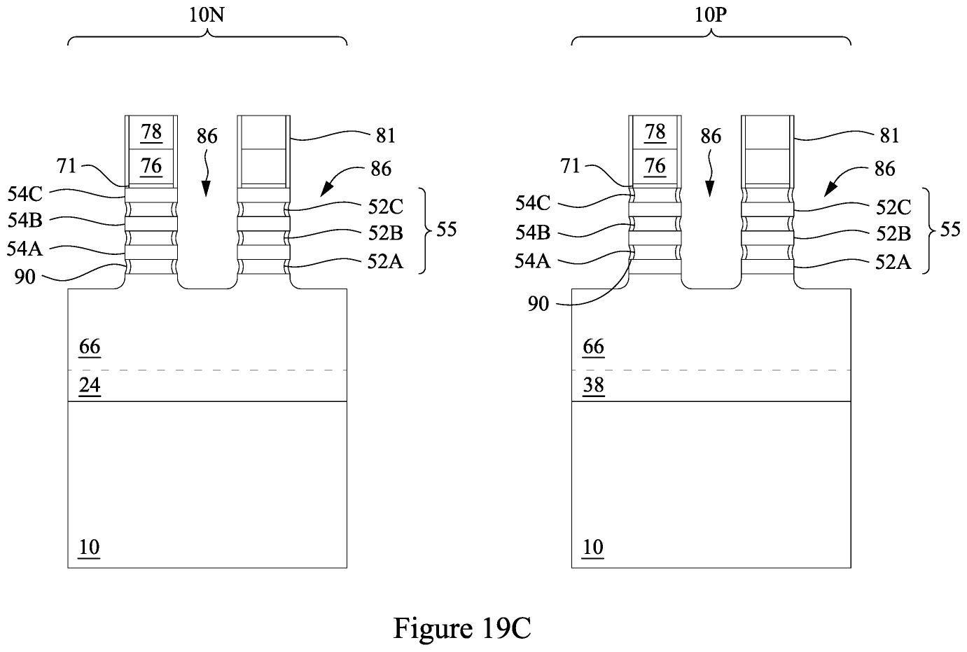

In FIGS. 19A-19C, first inner spacers 90 are formed in the sidewall recess 88. The first inner spacers 90 may be formed by depositing an inner spacer layer (not separately illustrated) over the structures illustrated in FIGS. 20A and 20B. The first inner spacers 90 act as isolation features between subsequently formed source/drain regions and a gate structure. As will be discussed in greater detail below, source/drain regions will be formed in the first recesses 86, while the first nanostructures 52 in the n-type region 10N and the second nanostructures 54 in the p-type region 10P will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54 in the n-type region 10N and flush with the sidewalls of the first nanostructures 52 in the p-type region 10P, the outer sidewalls of the first inner spacers 90 may extend beyond or be recessed from sidewalls of the second nanostructures 54 and/or the first nanostructures 52, respectively.

Moreover, although the outer sidewalls of the first inner spacers 90 are illustrated as being straight in FIG. 19B, the outer sidewalls of the first inner spacers 90 may be concave or convex. As an example, FIG. 19C illustrates an embodiment in which sidewalls of the first nanostructures 52 are concave, outer sidewalls of the first inner spacers 90 are concave, and the first inner spacers 90 are recessed from sidewalls of the second nanostructures 54 in the n-type region 10N. Also illustrated are embodiments in which sidewalls of the second nanostructures 54 are concave, outer sidewalls of the first inner spacers 90 are concave, and the first inner spacers 90 are recessed from sidewalls of the first nanostructures 52 in the p-type region 10P. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 20A-20C) by subsequent etching processes, such as etching processes used to form gate structures.

In FIGS. 20A-20C, epitaxial source/drain regions 92 are formed in the first recesses 86. In some embodiments, the source/drain regions 92 may exert stress on the second nanostructures 54 in the n-type region 10N and on the first nanostructures 52 in the p-type region 10P, thereby improving performance. As illustrated in FIG. 20B, the epitaxial source/drain regions 92 are formed in the first recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 in the n-type region 10N, e.g., the NMOS region, may be formed by masking the p-type region 10P, e.g., the PMOS region. Then, the epitaxial source/drain regions 92 are epitaxially grown in the first recesses 86 in the n-type region 10N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 10P, e.g., the PMOS region, may be formed by masking the n-type region 10N, e.g., the NMOS region. Then, the epitaxial source/drain regions 92 are epitaxially grown in the first recesses 86 in the p-type region 10P. The epitaxial source/drain regions 92 may include any acceptable material appropriate for p-type nano-FETs. For example, if the first nanostructures 52 are silicon germanium, the epitaxial source/drain regions 92 may comprise materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the multi-layer stack 56 and may have facets.

The epitaxial source/drain regions 92, the first nanostructures 52, the second nanostructures 54, and/or the substrate 10 may be implanted with dopants to form source/drain regions, similar to the process previously discussed for forming lightly-doped source/drain regions, followed by an annealing. The source/drain regions may have an impurity concentration of between about 1×10¹⁹ atom/cm³ and about 1×10²¹ atom/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 10N and the p-type region 10P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 20A. In other embodiments, adjacent epitaxial source/drain regions 92 remain separated after the epitaxy process is completed as illustrated by FIG. 20C. In the embodiments illustrated in FIGS. 20A and 20C, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI regions 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 20D illustrates an embodiment in which sidewalls of the first nanostructures 52 in the n-type region 10N and sidewalls of the second nanostructures 54 in the p-type region 10P are concave, outer sidewalls of the first inner spacers 90 are concave, and the first inner spacers 90 are recessed from sidewalls of the second nanostructures 54 and the first nanostructures 52, respectively. As illustrated in FIG. 20D, the epitaxial source/drain regions 92 may be formed in contact with the first inner spacers 90 and may extend past sidewalls of the second nanostructures 54 in the n-type region 10N and past sidewalls of the first nanostructures 52 in the p-type region 10P.

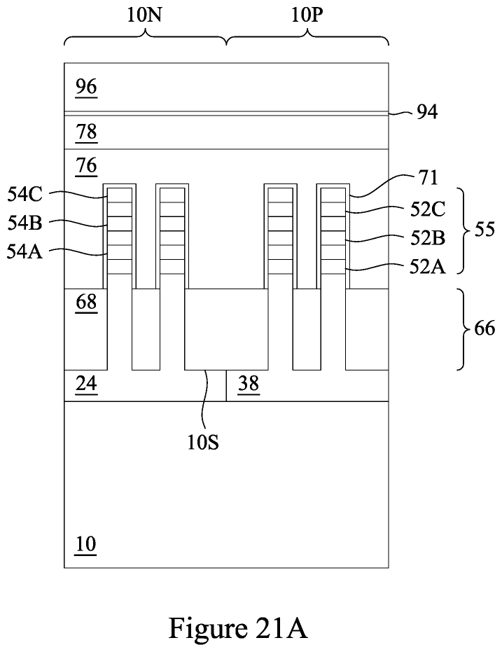

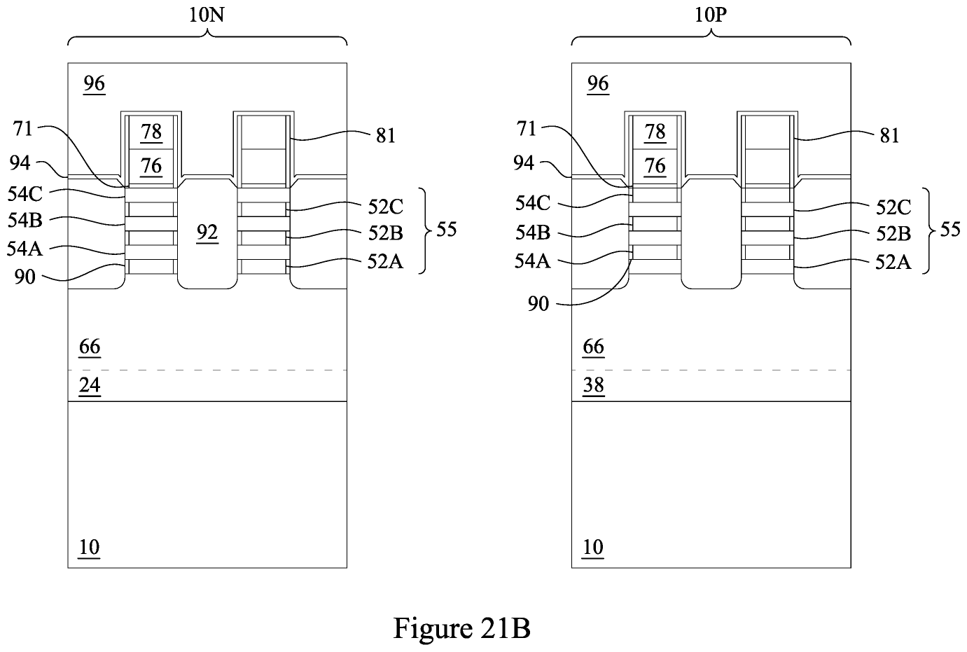

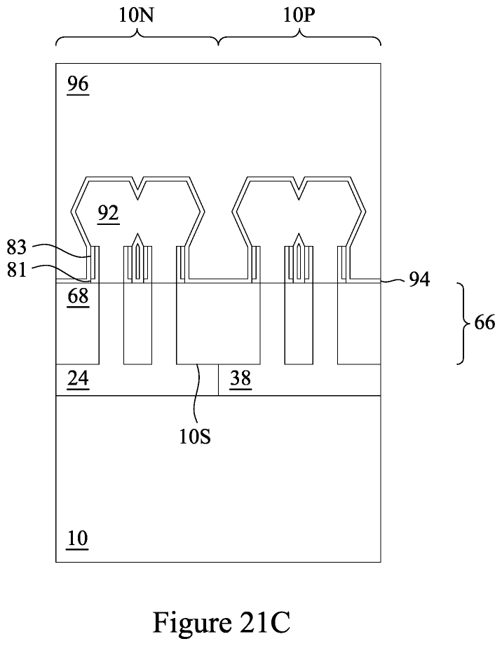

In FIGS. 21A-21C, a first interlayer dielectric (ILD) 96 is deposited over the structure illustrated in FIGS. 14A, 20B, and 20A (the processes of FIGS. 15A-20D do not alter the cross-section illustrated in FIG. 14A), respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying first ILD 96.

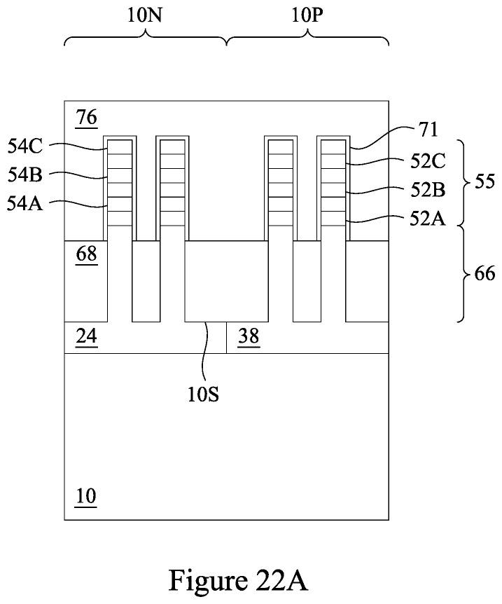

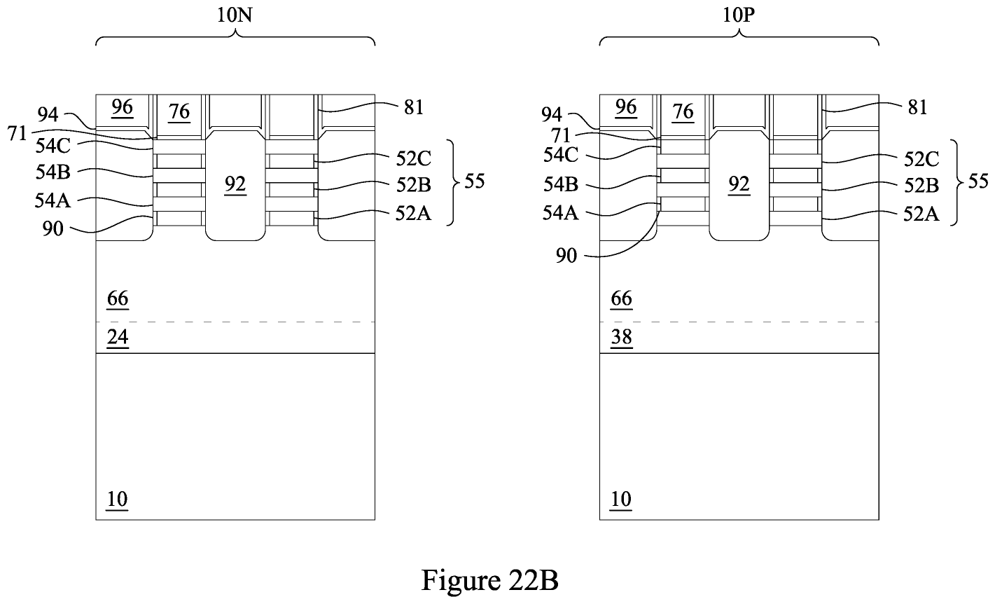

In FIGS. 22A-22C, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 72 are exposed through the first ILD 96. In some embodiments, the masks 78 may remain, in which case the planarization process levels the top surface of the first ILD 96 with top surface of the masks 78 and the first spacers 81.

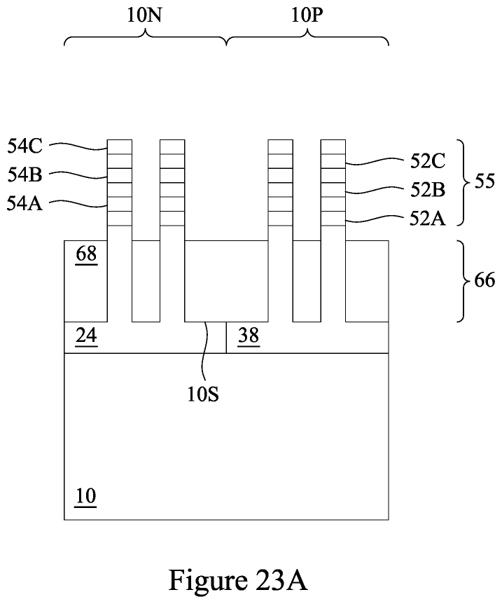

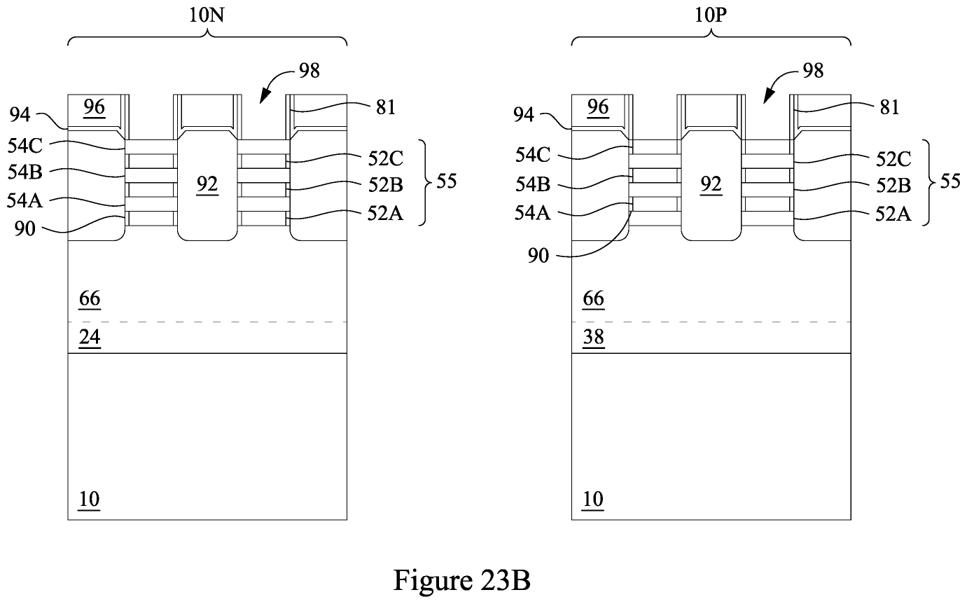

In FIGS. 23A and 23B, the dummy gates 76, and the masks 78 if present, are removed in one or more etching steps, so that second recesses 98 are formed. Portions of the dummy dielectric layers 60 in the second recesses 98 are also be removed. In some embodiments, the dummy gates 76 and the dummy dielectric layers 60 are removed by an anisotropic dry etching process. For example, the etching process may include a dry etching process using reaction gas(es) that selectively etch the dummy gates 76 at a faster rate than the first ILD 96 or the first spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy dielectric layers 60 may be used as etch stop layers when the dummy gates 76 are etched. The dummy dielectric layers 60 may then be removed after the removal of the dummy gates 76.

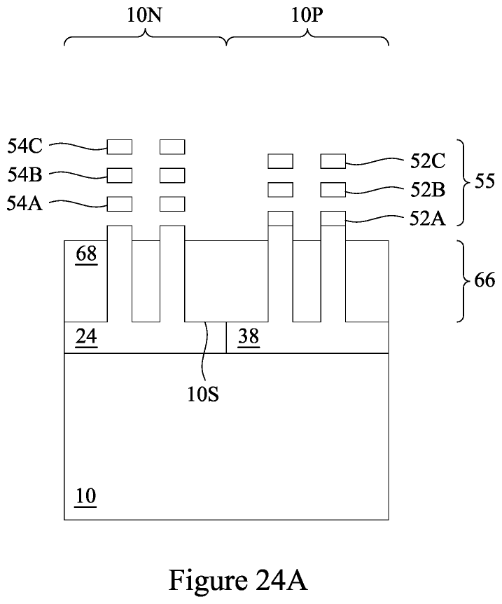

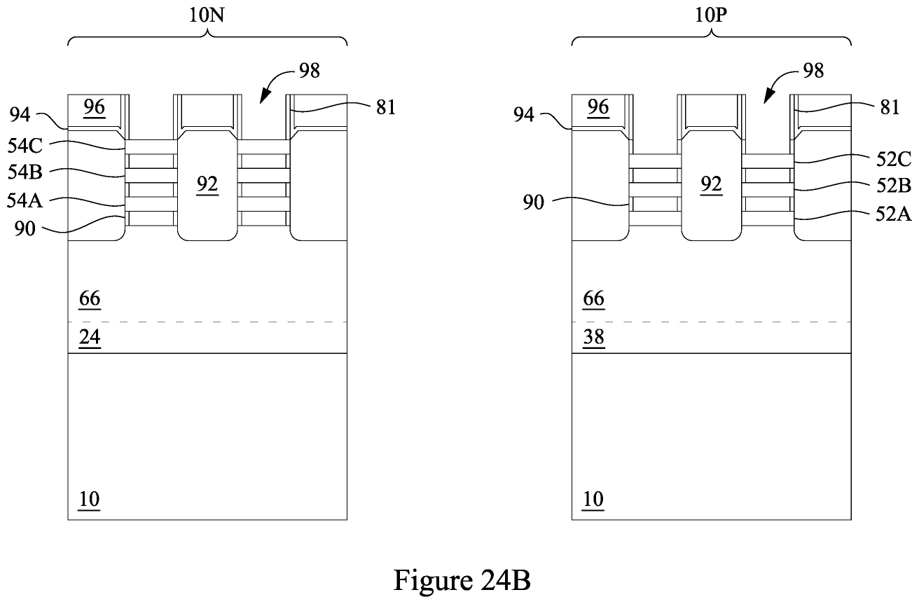

In FIGS. 24A and 24B, the first nanostructures 52 in the n-type region 10N and the second nanostructures 54 in the p-type region 10P are removed extending the second recesses 98. The first nanostructures 52 may be removed by forming a mask (not shown) over the p-type region 10P and performing an isotropic etching process such as wet etching or the like using etchants which are selective to the materials of the first nanostructures 52, while the second nanostructures 54, the substrate 10, the STI regions 68 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52 in the n-type region 10N.

The second nanostructures 54 in the p-type region 10P may be removed by forming a mask (not shown) over the n-type region 10N and performing an isotropic etching process such as wet etching or the like using etchants which are selective to the materials of the second nanostructures 54, while the first nanostructures 52, the substrate 10, the STI regions 68 remain relatively unetched as compared to the second nanostructures 54. In embodiments in which the second nanostructures 54 include, e.g., SiGe, and the first nanostructures 52 include, e.g., Si or SiC, hydrogen fluoride, another fluorine-based etchant, or the like may be used to remove the second nanostructures 54 in the p-type region 10P.

In other embodiments, the channel regions in the n-type region 10N and the p-type region 10P may be formed simultaneously, for example by removing the first nanostructures 52 in both the n-type region 10N and the p-type region 10P or by removing the second nanostructures 54 in both the n-type region 10N and the p-type region 10P. In such embodiments, channel regions of n-type nano-FETs and p-type nano-FETS may have a same material composition, such as silicon, silicon germanium, or the like. FIGS. 29A, 29B, and 29C illustrate a structure resulting from such embodiments where the channel regions in both the p-type region 10P and the n-type region 10N are provided by the second nanostructures 54 and comprise silicon, for example.

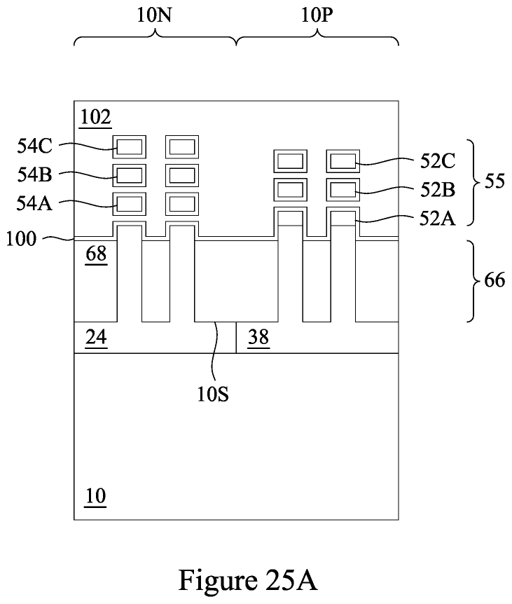

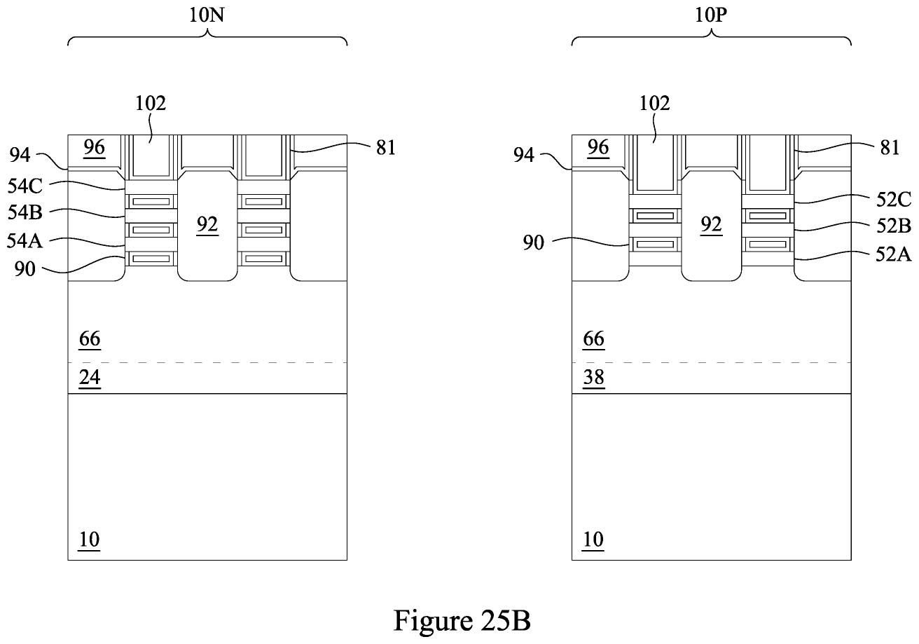

In FIGS. 25A and 25B, gate dielectric layers 100 and gate electrodes 102 are formed for replacement gates. The gate dielectric layers 100 are deposited conformally in the second recesses 98. In the n-type region 10N, the gate dielectric layers 100 may be formed on top surfaces and sidewalls of the substrate 10 and on top surfaces, sidewalls, and bottom surfaces of the second nanostructures 54, and in the p-type region 10P, the gate dielectric layers 100 may be formed on top surfaces and sidewalls of the substrate 10 and on top surfaces, sidewalls, and bottom surfaces of the first nanostructures 52. The gate dielectric layers 100 may also be deposited on top surfaces of the first ILD 96, the CESL 94, the first spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 10N and the p-type region 10P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 25A and 25B, the gate electrodes 102 may comprise any number of liner layers, any number of work function tuning layers, and a fill material. Any combination of the layers which make up the gate electrodes 102 may be deposited in the n-type region 10N between adjacent ones of the second nanostructures 54 and between the second nanostructure 54A and the substrate 10, and may be deposited in the p-type region 10P between adjacent ones of the first nanostructures 52.

The formation of the gate dielectric layers 100 in the n-type region 10N and the p-type region 10P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

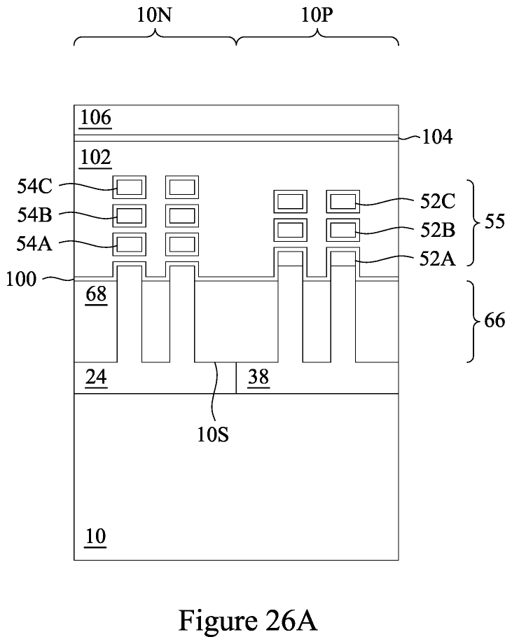

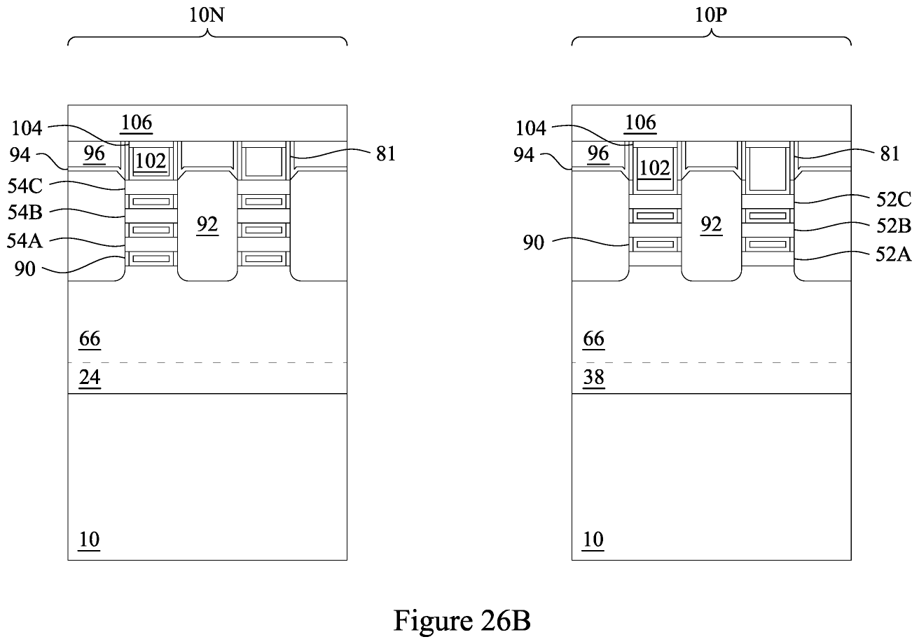

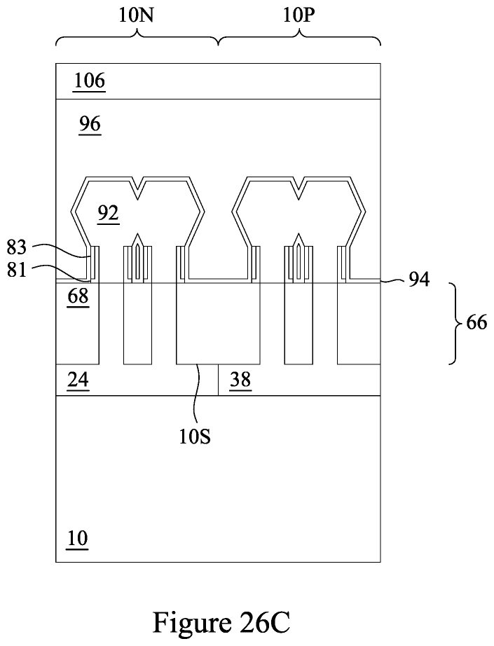

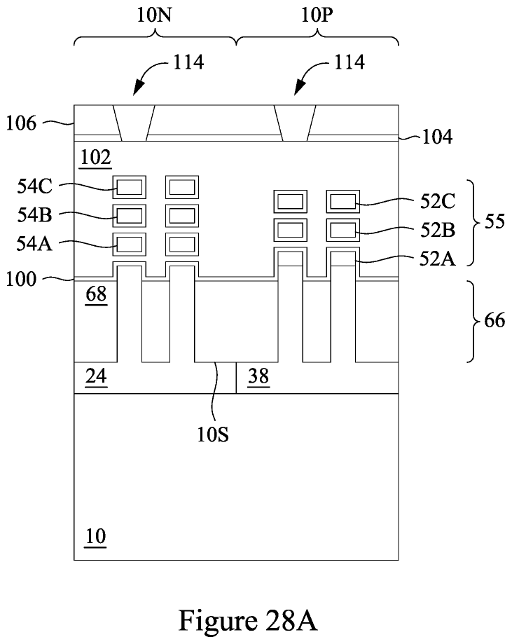

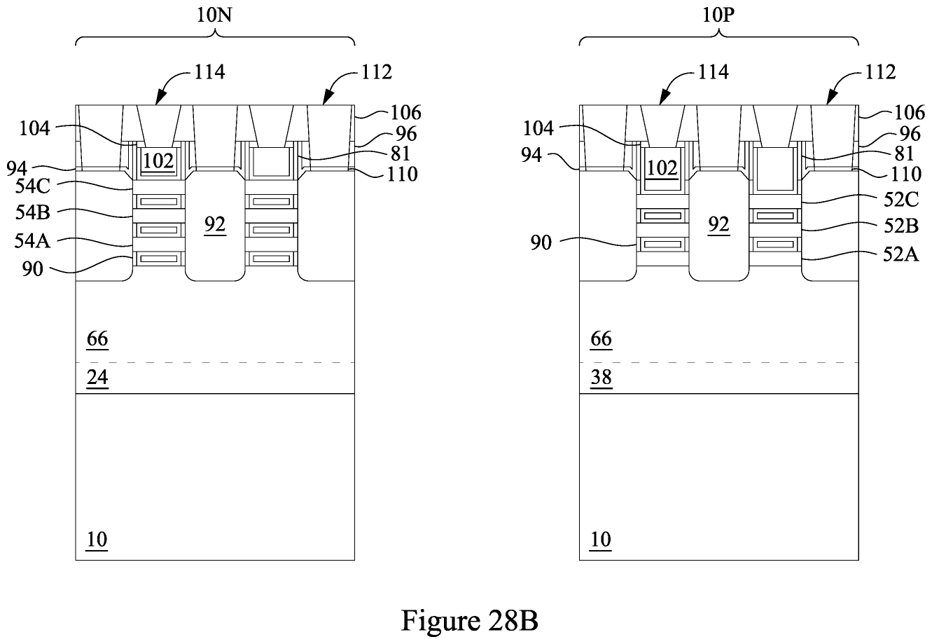

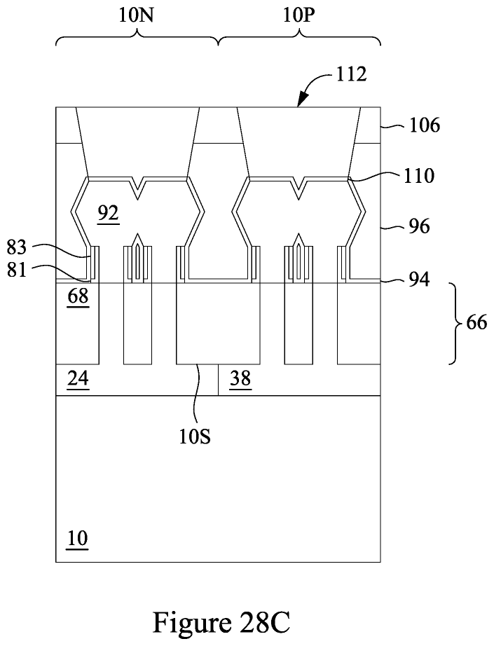

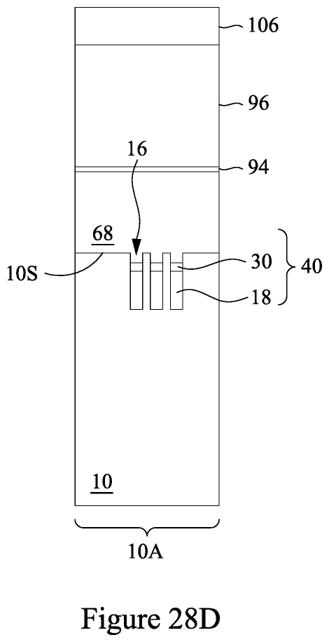

In FIGS. 26A-26C, the gate structure (including the gate dielectric layers 100 and the corresponding overlying gate electrodes 102) is recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the contacts 114, discussed below with respect to FIGS. 28A and 28B) penetrate through the gate mask 104 to contact the top surface of the recessed gate electrodes 102.

As further illustrated by FIGS. 26A-26C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

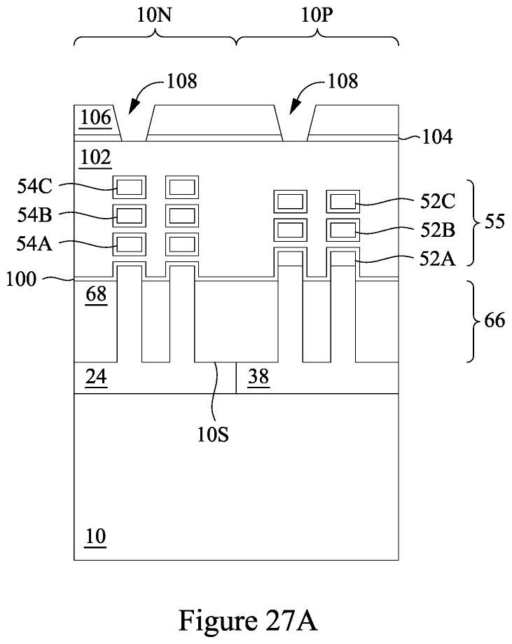

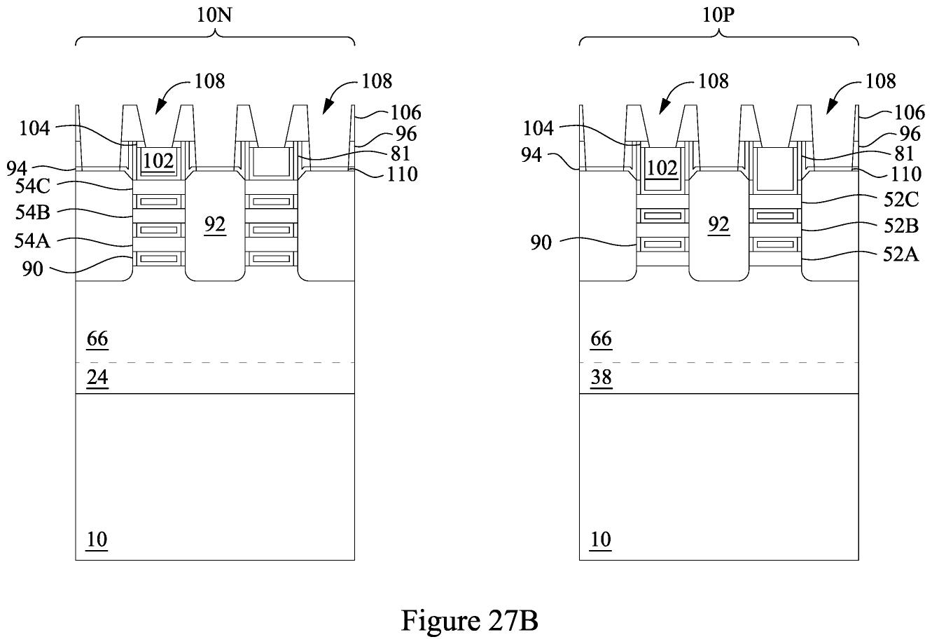

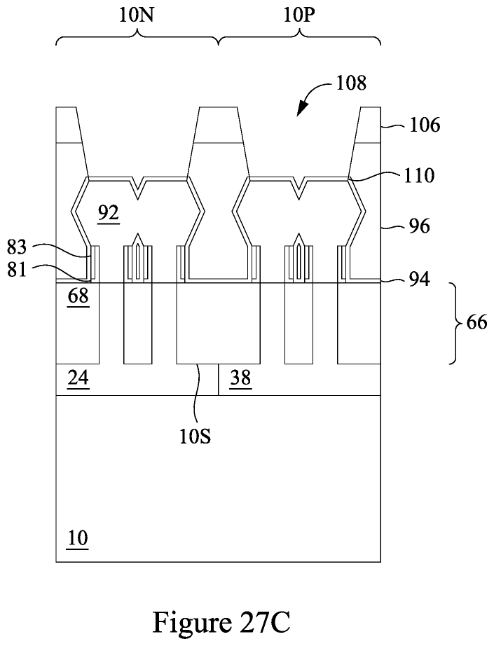

In FIGS. 27A-27C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 29B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts. After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal annealing process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 28A-C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate structure and/or silicide region 110 in the illustrated embodiment). The contacts 114 are electrically coupled to the gate structure and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material 118 may be copper, a copper alloy, silver, gold, tungsten, cobalt, aluminum, nickel, or the like. A planarization process, such as a CMP, may be performed to remove excess material from a surface of the second ILD 106. The structure in the alignment mark region 10A is illustrated in FIG. 28D. Additional processes may be further performed, including back-end-of-line (BEOL) processes, scribing the substrate 10 to separate IC chips, more, which are not particularly illustrated herein.

FIGS. 29A-C illustrate cross-sectional views of a device according to some alternative embodiments. FIG. 29A illustrates reference cross-section A-A′ illustrated in FIG. 1. FIG. 29B illustrates reference cross-section B-B′ illustrated in FIG. 1. FIG. 29C illustrates reference cross-section C-C′ illustrated in FIG. 1. In FIGS. 29A-C, like reference numerals indicate like elements formed by like processes as the structure of FIGS. 28A-C. However, in FIGS. 29A-C, channel regions in the n-type region 10N and the p-type region 10P comprise a same material. For example, the second nanostructures 54, which comprise silicon, provide channel regions for p-type nano-FETs in the p-type region 10P and for n-type nano-FETs in the n-type region 10N. The structure of FIGS. 29A-C may be formed, for example, by removing the first nanostructures 52 from both the p-type region 10P and the n-type region 10N simultaneously; depositing the gate dielectric layers 100 and the gate electrodes 102P (e.g., gate electrode suitable for a p-type nano-FET) around the second nanostructures 54 in the p-type region 10P; and depositing the gate dielectric layers 100 and the gate electrodes 102N (e.g., a gate electrode suitable for a n-type nano-FET) around the second nanostructures 54 in the n-type region 10N. In such embodiments, materials of the epitaxial source/drain regions 92 may be different in the n-type region 10N compared to the p-type region 10P as explained above.

Embodiments may achieve advantages. For example, utilizing techniques described above such as hard masks for hot implantation processes, may help control the lateral boundaries of p-well 24 and n-well 38, leading to a reduction of possible overlapping of the neighboring p-well 24 and n-well 38, thereby improving the junction between the p-well 24 and n-well 38 and improving the leakage from the p-well 24 or n-well 38.

In an embodiment, a semiconductor device includes a semiconductor substrate, the semiconductor substrate including a first fin and a second fin; a first well in the semiconductor substrate, wherein the first fin is in the first well, the first well being doped with a first dopant having a first conductivity type; a second well in the semiconductor substrate, wherein the second fin is in the second well, the second well being doped with a second dopant having a second conductivity type different from the first conductivity type; an alignment mark in the semiconductor substrate, wherein the alignment mark includes a lower portion formed of a first material and an upper portion formed of a second material different from the first material; and an isolation layer over the first fin, the second fin, the semiconductor substrate, and the alignment mark. In an embodiment, the first material is selected from the group consisting of silicon nitride, silicon oxynitride, silicon carbide, and combinations thereof, and the second material is, different than the first material, selected from the group consisting of silicon oxide, silicon nitride, silicon oxynitride, silicon carbide, and combinations thereof. In an embodiment, the semiconductor device further includes a stack of semiconductor channel regions extending over the first fin. In an embodiment, the alignment mark has a top surface below a major upper surface of the semiconductor substrate. In an embodiment, the isolation layer extends below the major upper surface of the semiconductor substrate. In an embodiment, the first material is doped with the first dopant and the second dopant. In an embodiment, the second material is doped with the second dopant. In an embodiment, the first material is doped with the first dopant, and the second material is non-doped. In an embodiment, the first material and the second material are doped with only the second dopant.

In another embodiment, a method of forming a method is provided. The method includes forming a trench in a semiconductor substrate; forming a first patterned mask over the semiconductor substrate, wherein the first patterned mask includes a first material filling the trench; implanting a first dopant through the first patterned mask for forming a first well in the semiconductor substrate, the first dopant having a first conductivity type; removing the first patterned mask over a major upper surface of the semiconductor substrate and partially removing the first material in the trench; forming a second patterned mask over the semiconductor substrate, wherein the second patterned mask includes a second material filling the trench and covering the first material; implanting a second dopant through the second patterned mask for forming a second well in the semiconductor substrate, the second dopant having a second conductivity type being different from the first conductivity type; after the second well is formed, removing the second patterned mask over the major upper surface of the semiconductor substrate, wherein at least a portion of the second material remains in the trench after removing the second patterned mask; etching the semiconductor substrate to from a first fin and a second fin, wherein the first fin is in the first well, and the second fin is in the second well; and forming an isolation layer over the semiconductor substrate, wherein the isolation layer is along a sidewall of the first fin and a sidewall of the second fin and covering the second material in the trench. In an embodiment, the etching the semiconductor substrate to form the first fin and the second fin includes etching at least a portion of the second material in the trench. In an embodiment, the isolation layer fills the trench and is in contact with the second material. In an embodiment, the implanting the first dopant through the first patterned mask includes implanting the first dopant into the first material in the trench. In an embodiment, the implanting the second dopant through the second patterned mask includes implanting the second dopant into the first material and the second material in the trench. In an embodiment, the first material is selected from the group consisting of silicon nitride, silicon oxynitride, silicon carbide, and combinations thereof. In an embodiment, the second material is different than the first material, selected from the group consisting of silicon oxide, silicon nitride, silicon oxynitride, silicon carbide, and combinations thereof.

In yet another embodiment, a method of forming a method is provided, and the method includes forming a trench in a substrate; forming a first hard mask over a major upper surface of the substrate and in the trench, wherein the first hard mask includes a first opening exposing a first region of the substrate; performing a first implantation process through the first opening of the first hard mask, to form a first well in the first region; etching the first hard mask while leaving a portion of the first hard mask in the trench; forming a second hard mask over the major upper surface of the substrate and over the portion of the first hard mask in the trench, wherein the second hard mask includes a second opening exposing a second region of the substrate; performing a second implantation process through the second opening of the second hard mask, to form a second well in the substrate, wherein the second well abuts the first well and has a conductivity opposite to the first well; etching the second hard mask to at least remove the second hard mask over the major upper surface of the substrate; depositing a stack of alternating first epitaxial layers and second epitaxial layers over the substrate and the second hard mask in the trench; and etching the stack and the substrate to form a first fin in the first well, a second fin in the second well, a first nanostructure stack over the first fin, and a second nanostructure stack over the second fin. In an embodiment, the second hard mask in the trench is etched while etching the stack and the substrate. In an embodiment, the method further includes forming an isolation layer adjacent the first fin, the second fin, and filling the trench. In an embodiment, the first hard mask and the second hard mask are formed of different materials.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device comprising:
a semiconductor substrate, the semiconductor substrate comprising a first fin and a second fin;
a first well in the semiconductor substrate, wherein the first fin is in the first well, the first well being doped with a first dopant having a first conductivity type;
a second well in the semiconductor substrate, wherein the second fin is in the second well, the second well being doped with a second dopant having a second conductivity type different from the first conductivity type;
an alignment mark in the semiconductor substrate, wherein the alignment mark comprises a lower portion formed of a first material and an upper portion formed of a second material different from the first material; and
an isolation layer over the first fin, the second fin, the semiconductor substrate, and the alignment mark.

2. The semiconductor device of claim 1, wherein the first material is selected from the group consisting of silicon nitride, silicon oxynitride, silicon carbide, and combinations thereof, and the second material is, different than the first material, selected from the group consisting of silicon oxide, silicon nitride, silicon oxynitride, silicon carbide, and combinations thereof.

3. The semiconductor device of claim 1, further comprising a stack of semiconductor channel regions extending over the first fin.

4. The semiconductor device of claim 1, wherein the alignment mark has a top surface below a major upper surface of the semiconductor substrate.

5. The semiconductor device of claim 4, wherein the isolation layer extends below the major upper surface of the semiconductor substrate.

6. The semiconductor device of claim 1, wherein the first material is doped with the first dopant and the second dopant.

7. The semiconductor device of claim 6, wherein the second material is doped with the second dopant.

8. The semiconductor device of claim 1, wherein the first material is doped with the first dopant, and the second material is non-doped.

9. The semiconductor device of claim 1, wherein the first material and the second material are doped with only the second dopant.

10. A method of forming a semiconductor device, the method comprising:
forming a trench in a semiconductor substrate;
forming a first patterned mask over the semiconductor substrate, wherein the first patterned mask comprises a first material filling the trench;
implanting a first dopant through the first patterned mask for forming a first well in the semiconductor substrate, the first dopant having a first conductivity type;
removing the first patterned mask over a major upper surface of the semiconductor substrate and partially removing the first material in the trench;
forming a second patterned mask over the semiconductor substrate, wherein the second patterned mask comprises a second material filling the trench and covering the first material;
implanting a second dopant through the second patterned mask for forming a second well in the semiconductor substrate, the second dopant having a second conductivity type being different from the first conductivity type;
after the second well is formed, removing the second patterned mask over the major upper surface of the semiconductor substrate, wherein at least a portion of the second material remains in the trench after removing the second patterned mask;
etching the semiconductor substrate to from a first fin and a second fin, wherein the first fin is in the first well, and the second fin is in the second well; and
forming an isolation layer over the semiconductor substrate, wherein the isolation layer is along a sidewall of the first fin and a sidewall of the second fin and covering the second material in the trench.

11. The method of claim 10, wherein the etching the semiconductor substrate to form the first fin and the second fin comprises etching at least a portion of the second material in the trench.

12. The method of claim 11, wherein the isolation layer fills the trench and is in contact with the second material.

13. The method of claim 10, wherein the implanting the first dopant through the first patterned mask comprises implanting the first dopant into the first material in the trench.

14. The method of claim 13, wherein the implanting the second dopant through the second patterned mask comprises implanting the second dopant into the first material and the second material in the trench.

15. The method of claim 10, wherein the first material is selected from the group consisting of silicon nitride, silicon oxynitride, silicon carbide, and combinations thereof.

16. The method of claim 10, wherein the second material is, different than the first material, selected from the group consisting of silicon oxide, silicon nitride, silicon oxynitride, silicon carbide, and combinations thereof.

17. A method of forming a semiconductor device, the method comprising:
forming a trench in a substrate;
forming a first hard mask over a major upper surface of the substrate and in the trench, wherein the first hard mask comprises a first opening exposing a first region of the substrate;
performing a first implantation process through the first opening of the first hard mask, to form a first well in the first region;
etching the first hard mask while leaving a portion of the first hard mask in the trench;
forming a second hard mask over the major upper surface of the substrate and over the portion of the first hard mask in the trench, wherein the second hard mask comprises a second opening exposing a second region of the substrate;
performing a second implantation process through the second opening of the second hard mask, to form a second well in the substrate, wherein the second well abuts the first well and has a conductivity opposite to the first well;
etching the second hard mask to at least remove the second hard mask over the major upper surface of the substrate;
depositing a stack of alternating first epitaxial layers and second epitaxial layers over the substrate and the second hard mask in the trench; and
etching the stack and the substrate to form a first fin in the first well, a second fin in the second well, a first nanostructure stack over the first fin, and a second nanostructure stack over the second fin.

18. The method of claim 17, wherein the second hard mask in the trench is etched while etching the stack and the substrate.

19. The method of claim 18, further comprising forming an isolation layer adjacent the first fin, the second fin, and filling the trench.

20. The method of claim 17, wherein the first hard mask and the second hard mask are formed of different materials.
